(19) United States
(12) Patent Application Publication
(10) Pub. No.: US 2026/0334081 A1
(43) Pub. Date: Oct. 22, 2026

(54) SENSOR NOISE REDUCTION AND MANUFACTURING METHODS

(71) Applicant: OBSIDIAN SENSORS, INC., San Diego, CA (US)

(72) Inventors: John HONG, San Diego, CA (US); Tallis CHANG, San Diego, CA (US); Edward CHAN, San Diego, CA (US); Sean ANDREWS, San Diego, CA (US); Bing WEN, San Diego, CA (US); Heesun SHIN, San Diego, CA (US); Alan LEWIS, San Diego, CA (US); Jeremy HONG, San Diego, CA (US)

(21) Appl. No.: 19/109,839

(22) PCT Filed: Sep. 6, 2023
(86) PCT No.: PCT/US2023/073515

§ 371 Date: Mar. 7, 2025

Related U.S. Application Data
(60) Provisional application No. 63/404,907, filed on Sep. 8, 2022.
(60) Provisional application No. 63/404,911, filed on Sep. 8, 2022.
(60) Provisional application No. 63/404,914, filed on Sep. 8, 2022.

(51) Int. Cl. H10N 19/00; G01J 5/08; G01J 5/20; H04N 25/60; H04N 25/703; H04N 25/709; H04N 25/77

(52) U.S. Cl. CPC H10N 19/00; G01J 5/0859; G01J 5/20; H04N 25/60; H04N 25/703; H04N 25/709; H04N 25/77; G01J 2005/202

(57) ABSTRACT

Noise reduction and manufacturing methods for sensors of an electronic device are disclosed. In some embodiments, the device comprises a lid comprising an opening covered by a window cap. In some embodiments, the device comprises pressure sensors. In some embodiments, a method comprises induction heating for bonding the device. In some embodiments, a method comprises averaging readout values of successive frames from the sensors. In some embodiments, a method comprises reading out the sensors at a first frequency during a first time period and at a second frequency during a second time period. In some embodiments, residue filaments are attached to the sensors. In some embodiments, the device is thermally isolated from a housing of the device. In some embodiments, the device comprises sensors for measuring temperature. In some embodiments, the device comprises a bias voltage generator for providing a bias voltage to the sensors.

### CROSS-REFERENCE TO RELATED APPLICATIONS

This application claims the benefit of U.S. Provisional Application No. 63/404,907, filed on Sep. 8, 2022, U.S. Provisional Application No. 63/404,911, filed on Sep. 8, 2022, and U.S. Provisional Application No. 63/404,914, filed on Sep. 8, 2022, the entire disclosures of which are herein incorporated by reference for all purposes.

### FIELD

This disclosure generally relates to noise reduction and manufacturing methods for sensors of an electronic device.

### BACKGROUND

Sensors (e.g., uncooled microbolometers, MEMS-based sensors) sensitive to gas environments may require vacuum encapsulation that can provide a gas pressure ambient (e.g., lower than 10 mTorr). In the case of the microbolometer, the encased bolometer may be capable of outgassing volatiles species that potentially limit the degree of vacuum that can be achieved.

One of the potential issues for vacuum sealing is outgassing from the devices (e.g., MEMS structures, cover, etc.) that are being sealed. As the temperature of the bonding parts is increased, the outgassing may increase. AuSn (80/20) may be used for vacuum packaging. However, with a melting temperature of 283 C, AuSn bonding may be performed at 300 C~320 C. Once the bonding is complete, the samples are cooled to below 280 C before the ambient vacuum is broken and the bonded sample is cooled to room temperature. This may take several minutes and longer depending on the bonding tool cooling rate. During this time (e.g., minutes, tens of minutes), the sample may outgas internally at an elevated temperature after the seal is established.

The use of sensors (e.g., microbolometers) for thermal imaging may be hampered by spatiotemporal noise and nonuniformities, which may be corrected by post-detection processing. However, 1/f noise may be present in the detection process and may contribute to spatial and temporal artifacts in thermal images and videos.

When a sensor pixel (e.g., a MEMS pixel, a microbolometer pixel) is encapsulated in a low-pressure environment (e.g., a vacuum environment), dynamic instabilities stemming from high-Q resonances may cause issues. Furthermore, the pixel responses may be temperature-dependent, and the temperature-dependent effects may be exacerbated by nonuniformities across the array.

### SUMMARY

Noise reduction and manufacturing methods for sensors of an electronic device are disclosed. In some embodiments, the electronic device comprises a glass substrate and a plurality of pixels. In some embodiments, the plurality of pixels is configured to absorb radiation. In some embodiments, the plurality of pixels comprises bolometer pixels.

In some embodiments, the electronic device comprises a lid comprising an opening covered by a window cap. In some embodiments, the lid is bonded to the glass substrate.

In some embodiments, the electronic device comprises a sensor array comprising an active area and a dummy pixel area. In some embodiments, the active area comprises the sensors and the dummy pixel area comprises pressure sensors.

In some embodiments, the electronic device is bonded via induction heating.

In some embodiments, the readout values of successive frames from the sensors are averaged in accordance with a determination that a difference between the values of the successive frames are lower than the threshold value.

In some embodiments, the sensors are readout at a first frequency during a first time period and at a second frequency during a second time period.

In some embodiments, residue filaments are attached to the sensors. In some embodiments, the device is thermally isolated from a housing of the device.

In some embodiments, the device comprises a sensor panel, and the sensor panel comprises the sensors and a boundary area. In some embodiments, the boundary area comprises sensors for measuring temperature.

In some embodiments, the device comprises a bias voltage generator for providing a bias voltage to the sensors. In some embodiments, the device comprises a readout circuit for reading out measurements from the sensors.

The embodiments disclosed above are only examples, and the scope of this disclosure is not limited to them. Particular embodiments may include all, some, or none of the components, elements, features, functions, operations, or steps of the embodiments disclosed above. Embodiments according to the invention are in particular disclosed in the attached claims directed to a method of operation, a method of manufacturing, a storage medium, a system, a device, and a computer program product, wherein any feature mentioned in one claim category, e.g., method of operation, can be claimed in another claim category, e.g., system, a device, method of manufacturing, as well. The dependencies or references back in the attached claims are chosen for formal reasons only. However, any subject matter resulting from a deliberate reference back to any previous claims (in particular multiple dependencies) can be claimed as well, so that any combination of claims and the features thereof are disclosed and can be claimed regardless of the dependencies chosen in the attached claims. The subject-matter which can be claimed comprises not only the combinations of features as set out in the attached claims but also any other combination of features in the claims, wherein each feature mentioned in the claims can be combined with any other feature or combination of other features in the claims. Furthermore, any of the embodiments and features described or depicted herein can be claimed in a separate claim and/or in any combination with any embodiment or feature described or depicted herein or with any of the features of the attached claims.

### BRIEF DESCRIPTION OF THE DRAWINGS

FIG. 1 illustrates an exemplary electronic device, in accordance with embodiments of this disclosure.

FIG. 2 illustrates an exemplary electronic device, in accordance with embodiments of this disclosure.

FIG. 3 illustrates an exemplary process for manufacturing an electronic device, in accordance with embodiments of this disclosure.

FIG. 4 illustrates an exemplary component of an electronic device, in accordance with embodiments of this disclosure.

FIG. 5 illustrates an exemplary process for manufacturing an electronic device, in accordance with embodiments of this disclosure.

FIGS. 6A-6C illustrate exemplary processes for manufacturing an electronic device, in accordance with embodiments of this disclosure.

FIGS. 7A-7B illustrate exemplary sensors for an electronic device, in accordance with embodiments of this disclosure.

FIG. 8 illustrates exemplary relationships of sensors of an electronic device, in accordance with embodiments of this disclosure.

FIGS. 9A-9C illustrate exemplary processes for manufacturing an electronic device, in accordance with embodiments of this disclosure.

FIG. 10 illustrates exemplary noise spectrum and power transfer function, in accordance with embodiments of this disclosure.

FIG. 11 illustrates exemplary noise spectrum and power transfer function, in accordance with embodiments of this disclosure.

FIG. 12 illustrates exemplary oscillation waveforms, in accordance with embodiments of this disclosure.

FIGS. 13A-13B illustrate exemplary sensor structures, in accordance with embodiments of this disclosure.

FIG. 14 illustrates an exemplary attachment of an electronic device, in accordance with embodiments of this disclosure.

FIG. 15 illustrates an exemplary sensor array, in accordance with embodiments of this disclosure.

FIGS. 16-21 illustrates exemplary circuits of an electronic device, in accordance with embodiments of this disclosure.

FIG. 22 illustrates a method of manufacturing an electromechanical system, in accordance with embodiments of this disclosure.

FIG. 23 illustrates an exemplary sensor, in accordance with embodiments of this disclosure.

### DETAILED DESCRIPTION

In the following description of embodiments, reference is made to the accompanying drawings which form a part hereof, and in which it is shown by way of illustration specific embodiments which can be practiced. It is to be understood that other embodiments can be used and structural changes can be made without departing from the scope of the disclosed embodiments.

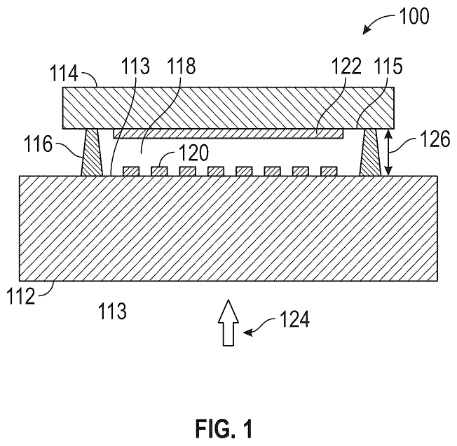

FIG. 1 illustrates an electronic device 100. As illustrated, the electronic device 100 includes a substrate 112, a lid 114, spacers 116, cavity 118, pixels 120, and reflector 122. As illustrated, the cavity 118 is defined by the spacers 116, the surface 115 of the lid 114, and the surface 113 of the substrate 112.

In some embodiments, the electronic device 100 includes a vacuum port for vacuum encapsulation (not shown). In some embodiments, the vacuum port can integrate into the spacers 116. In some examples, the vacuum seal can be made with metal solders or glass to silicon or glass to glass or silicon to silicon laser welding methods.

In some embodiments, the electronic device 100 is a camera sensor in an imaging system. For example, radiation 124 passes a first surface of the substrate 112 and through a second surface 113 (e.g., the surface on which the pixels 120 are disposed) of the substrate 112. The radiation 124 passes through second surface 113 and is at least partially absorbed by pixels 120 (or absorbers of the pixels 120). Radiation that is not absorbed by the pixels 120 can travel to the reflector 122 and be redirected back to pixels 120. In some embodiments, the electronic device 100 is bolometer device. In some embodiments, the pixels 120 or its absorbers are configured to absorb radiation in THz frequencies (e.g., the absorbers are THz bolometers absorbers) or radiation in other frequencies. In some embodiments, each of the pixels 120 includes an absorber.

Although a plurality of pixels is shown, it is understood that the electronic device 100 may include a single pixel 120 in cavity 118. In some embodiments, the substrate 112 is configured to pass radiation (e.g., radiation in the terahertz (THz) band or another band, incoming radiation 124).

As an exemplary advantage, the electronic device 100 can efficiently absorb radiation 124 and may include less structural components compared to alternative solutions. By disposing the pixels on the second surface of the substrate and using a substrate (e.g., a glass substrate) configured to pass the radiation, less structural components may be required to position the pixels 120 or absorbers opposing the reflector 122. An alternative solution may include suspending the absorbers above a reflector, using additional structural components to encapsulate the device, and using longer spacers to accommodate the suspended absorbers. By disposing the pixels or absorbers on the substrate configured to pass radiation, radiation can be absorbed efficiently—radiation that is not initially absorbed by pixels 120 may be absorbed after it is being redirected from the reflector 122 and elements of the camera sensor can be minimized—the substrate can function as both a radiation transmission component and a structural component.

In some examples, the substrate 112 may be manufactured from glass. For example, an IMG process (exemplary processes are disclosed in International Application No. PCT/US2019/022338, the entirety of which is incorporated herein by reference) is used to realize microbolometer arrays (e.g., pixels 120) with pixel pitch in the range 20-500 μm. The 500 μm pitch may correspond to 1 mm wavelength (300 GHz). In some embodiments with a HD resolution (e.g., FHD: 1920×1080) camera sensor, the sensor active area could occupy an area in the range 38.4×21.6 mm² (=829.44 mm²) to 960×540 mm² (=518,400 mm²). Advantageously, embodiments herein accommodate such large areas without dividing up the sensor real estate into sub-panels.

In some embodiments, the substrate can include materials with lower loss in the wavelength of interest (e.g., millimeter wavelengths, THz frequencies, 0.1 millimeter to 3 millimeters, other wavelengths) such as fused silica and quartz. In some embodiments, the thickness of the substrate 112 is in the range of 50 to 200 μm using substrate glass. For example, at the beginning of fabrication procedure, a thin glass substrate can be attached to a thicker glass substrate with a release layer in between the two substrates. The fabrication procedure can be performed on top of the composite substrate formed by the thin glass substrate and the thicker glass substrate. After a device is formed (e.g., before or after vacuum encapsulation), the device is removed from the thicker substrate (in this embodiment, the thicker substrate can be understood to be a handling layer). The device may then be attached to a window material that may have low loss at the wavelength of interest and can provide mechanical integrity.

For example, loss can be reflection loss from surfaces, which may be controlled by the refractive index (e.g., deviation from that of air, which is n=1). Another example of loss may be bulk absorption in the substrate. In some embodiments, the two losses are equal or less than 20%. In some examples, for mechanical integrity, the composite substrate can be at least 0.5 mm thick; as the array size increases, the thickness may be increased to 2 mm or greater.

For example, polymers such as poly 4-methyl pentene can have an absorption coefficient that is less than 0.05 cm-1, which translates to a bulk absorption of 2.5% in a substrate that is 5 mm thick. The reflection loss at a surface adjacent to air (e.g., where incoming radiation initially passes) can be controlled by anti-reflective structures that can be molded into the polymer surface. The anti-reflective structures can include inorganic materials such as fused silica, quartz, and sapphire.

In some embodiments, if the substrate is sufficiently thin and may not sufficiently mechanically support a vacuum in the cavity, additional spacers may be used (e.g., to additionally support the substrate and the lid, in the pixel) for mechanical support and maintaining the distance between the absorbers and the reflector.

As used herein, millimeter wave and terahertz are not limited to single digit quantities associated with these units, it is understood that “millimeter wave” may include wavelengths less than 1 millimeter or greater than 10 millimeters, and “terahertz” may include frequencies less than 1 THz or greater than 10 THz. Although examples of the disclosed sensors are described to absorb radiation having specific wavelengths or frequencies, it should be appreciated that the described wavelengths and frequencies are exemplary, and the disclosed sensors may absorb radiation having different wavelengths or frequencies than described.

In some examples, the pixels 120 are disposed on surface 113 of the substrate 112. In some examples, the substrate 112 includes TFT circuitry (e.g., TFT circuitry that enables control and readout of sensor elements and is coupled to readout circuits) associated with pixel readout. In some examples, the substrate 112 may include non-TFT elements.

In some embodiments, the lid 114 comprises a surface 115, and the reflector 122 is positioned on the surface 115 (the surface of the lid facing the absorber of pixels 120). In some examples, the reflector 122 is part of the lid 114. For example, the lid 114 redirects radiation to the pixels 120. In some embodiments, as illustrated in FIG. 1, the reflector 122 is attached to the surface of the lid 114. In some embodiments, the reflector is the lid. For example, the reflector is structurally part of the lid and is located on a surface of the lid. As another example, the lid is a reflective material. In some embodiments, the reflector is inside the lid (e.g., the lid allows radiation to pass and reach the reflector that is inside the lid). In some embodiments, the reflector 122 is positioned on the opposite side of the substrate 112 as the pixels 120 (and absorber). In some embodiments, the lid 114 is opaque to the incoming radiation. In some embodiments, the lid 114 provides a structural encapsulation for the electronic device 100. In some embodiments, the lid 114 is a capping plate.

In some embodiments, the cavity 118 is in a vacuum. In some embodiments, the lid is configured to withstand the vacuum and present a hermetic barrier to maintain the vacuum. The lid should be otherwise opaque to radiation. In some embodiments, the lid includes a transparent dielectric layer to prevent corrosion during manufacturing and the pixel is designed for the electromagnetic properties of the transparent dielectric layer to optimize absorption.

In some embodiments, the lid is configured to withstand a vacuum in the cavity and present an effective hermetic barrier to maintain the vacuum. In some embodiments, the lid incorporates a transparent dielectric layer, which may advantageously provide a surface treatment to prevent corrosion during manufacturing. The electromagnetic properties of the dielectric layer are fully accounted for in the pixel design (e.g., absorption properties). For example, the pixel is designed for optimal absorption at a position that enables constructive interference between an incoming radiation and a directed radiation from a reflector.

In some embodiments, the substrate 112 and the reflector 122 are separated by a gap 126 related to the wavelength of the radiation. For example, if the reflector 122 is comprised of metal, radiation redirected from the reflector 122 can be 180 degrees out of phase from the incident radiation. In this example, the reflector 122 can be placed at a quarter wavelength away from the pixels 120 to allow the radiation to be absorbed at a point of constructive interference (e.g., the incoming radiation and the redirected radiation are optimally constructively interfering with each other at the pixel locations). In some examples, the reflector 122 can include a layer of metal with high conductivity in the frequencies of interest, with the layer at least several times thicker than the skin depth.

In some embodiments, the reflector comprises a plurality of reflectors each corresponding to a respective pixel (not shown). In some embodiments, the separation between a respective reflector and a respective pixel is dependent on a wavelength of the incoming radiation. For example, the electronic device 100 may be configured to receive incoming radiation having two different wavelengths, and the electronic device 100 may include two reflectors having two different separation distances between the respective reflector and the respective pixel (e.g., first separation at a quarter of a first wavelength and second separation at a quarter of a second wavelength).

In some embodiments, the spacers 116 separate the substrate 112 and the lid 114, as illustrated. In some embodiments, the spacers 116 may be formed from a sacrificial layer when the lid or the substrate is formed. After the formation of the lid or the substrate, material from the sacrificial layer is removed to form the spacers 116. It is understood that the spacer 116 may be formed from other materials and/or other methods (exemplary methods of manufacturing spacers can be found in International Application No. PCT/US2019/022338, the entirety of which is incorporated herein by reference). In some embodiments, the spacers 116 are part of the lid 114. In some embodiments, the spacers 116 are part of the substrate 112.

In some embodiments, the spacers 116 can include two layers of dissimilar materials. This may be advantageous at wavelengths where a thick layer of sacrificial material is impractical for creating the spacers 116. In some embodiments, one layer is a conductive layer (e.g., a metal layer) and the other layer is a dielectric layer. The top layer can have considerably higher tensile stress than the lower layer. This may advantageously allow the spacer to launch upward to neutralize the composite stress gradient when the structure is released from the sacrificial layer that held elements in place during the manufacturing process. The amount of stress difference coupled with the spacer length can result in a net displacement beyond the original sacrificial gap thickness.

As an exemplary advantage, a thinner sacrificial layer can be used to form the spacers 116 in place of a thicker sacrificial layer. This may be desirable for camera sensors operating in THz frequencies because the required sacrificial layer thickness may be large and costly.

In some embodiments, the spacers can be created by etching with a mask. In some embodiments, the spacers can be molded or etched based on the structural material used for lid.

It should be appreciated that the components described with respect to FIG. 1 may comprise examples described with respect to the other Figures. It should also be appreciated that the components described with respect to FIG. 1 may be manufactured via examples described with respect to the other Figures. For example, the pixels, hinges, and circuits described with respect to the other Figures may be implemented on electronic device 100.

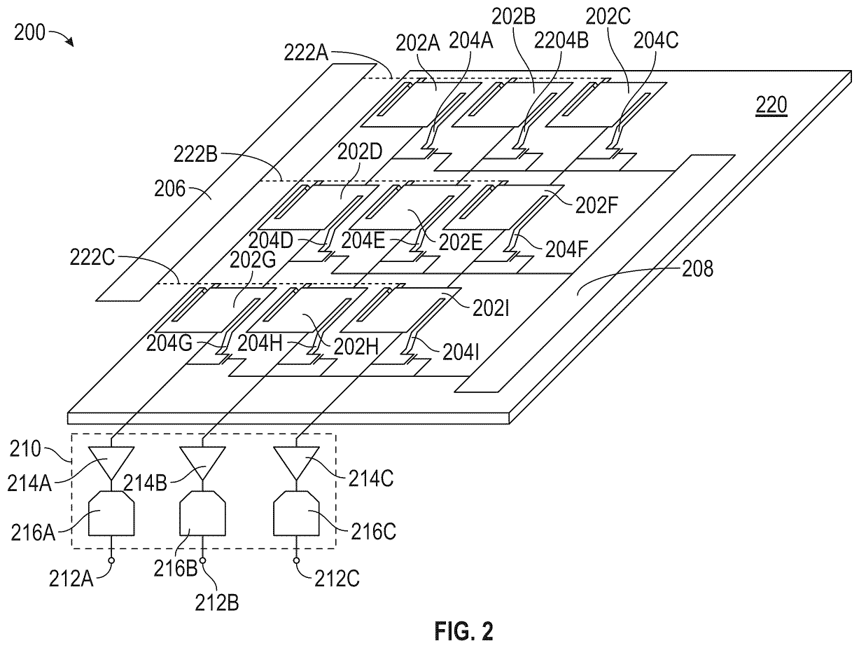

FIG. 2 illustrates an exemplary electronic device, according to embodiments of the disclosure. As illustrated, electronic device 200 comprises pixels 202A-202I, hinges 204A-204I, bias circuit 206, row circuit 208, readout circuit 210, outputs 212A-212C, and substrate 220. In some embodiments, electronic device 100 comprises electronic device 200. In some embodiments, the pixels 120 comprise one or more of pixels 202A-202I. In some embodiments, substrate 112 comprises substrate 220.

In some embodiments, the electronic device 200 comprises a MEMS device, and the pixels 202A-202I comprise MEMS sensors. In some embodiments, the pixels 202A-202I comprise bolometers. In some embodiments, the bolometers are configured to sense long-wave infrared (LWIR) radiation. In some embodiments, the pixels 202A-220I each comprise two nodes, and a resistance between the two nodes varies depending on radiation received by a pixel. Accordingly, when a voltage is applied across the two nodes of the pixel (e.g., between bias voltage and column line voltage), a current flows through the pixel, and the current is indicative of the pixel resistance (and hence, the radiation may be quantified (e.g., temperature)). In some embodiments, the hinges 204A-204I are configured to support a respective pixel 202A-202I. In some embodiments, as illustrated in FIG. 2, the pixels and hinges are arranged in a rectangular grid, and the pixels and hinges have a same pitch. That is, in some embodiments, adjacent pixels and adjacent hinges have same spacings.

In some embodiments, the pixels 202A-202I comprise an absorber (e.g., an absorbing layer) suspended above the substrate 220, and the hinges 204A-204I are configured to thermally isolate the pixels from the substrate. In some embodiments, the electronic device 200 comprises mirrors (e.g., reflector 122), each between a pixel and the substrate, and the hinges 204A-204I are configured to position the pixel at a position with respect to the mirror that increases absorption (e.g., increases absorption for LWIR radiation, quarter wavelength between absorber and mirror).

In some embodiments, the absorber comprises a resistive element having a high thermal coefficient of resistance (TCR) (e.g., such that the resistance of corresponding pixel scales with temperature, 1-5% per degree Celsius, following a relationship TCR=(1/R) (dR/dT)). In some embodiments, the absorber comprises metals, metal oxides, and metal oxynitrides, such as Ti, TiOxNy, V, MoCr, ITO. In some embodiments, a thickness of the absorber is designed such that the absorber's electromagnetic surface impedance matches that of free space (e.g., to increase absorption).

In some embodiments, the hinges 204A-204I comprise an electrically conductive component. In some embodiments, the pixels 202A-202I are electrically connected to a respective bias line (e.g., one of bias lines 222A-222C) and a corresponding pixel switch via the conductive hinges. In some embodiments, the thickness, length, width, and thermal conductance of the hinge affects sensitivity of a corresponding pixel, which may be expressed as noise-equivalent temperature difference (NETD). In some embodiments, if kth is the effective thermal conductivity of the hinge material (e.g., a single material, a composite of different materials (e.g., layered together)), the thermal conductance of a hinge is given by:

$${G}_{t h} = {k}_{th} \frac{W T}{L}$$

where W is the hinge width, T is the hinge thickness, and L is the hinge length. Examples of hinges are described in more detail herein.

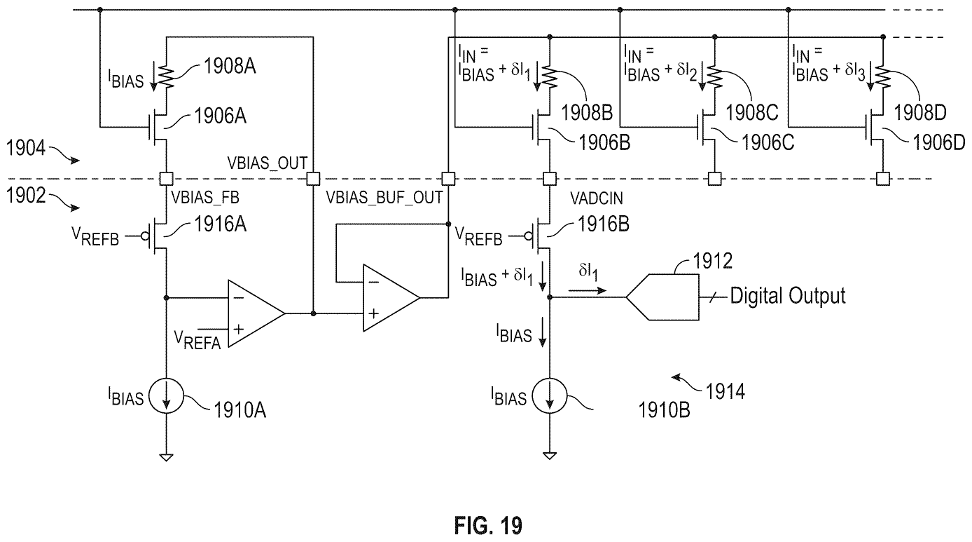

In some embodiments, the bias circuit 206 (e.g., as described with respect to FIGS. 16-21) is configured to provide a bias voltage to a respective row of pixels via a bias line (e.g., bias lines 222A-222C). For example, a row of pixels comprises pixels 202A, 202B, and 202C, and the row of pixels is electrically coupled to the bias line 222A. Examples of the bias circuit 206 are described herein.

In some embodiments, the row circuit 208 comprises a row multiplexing circuit. In some embodiments, the row multiplexing circuit is configured to select a row of pixels at each time to electrically couple the row of pixels to the readout circuit 210 (e.g., enabling signals generated by a row of pixels to be readout in a parallel fashion). Examples of the readout circuit 210 are additionally described with respect to FIGS. 18-21. In some embodiments, the row circuit 208 coordinates with the bias circuit 206, such that a bias voltage is provided to a row of pixels that are electrically coupled (by the row circuit) to the readout circuit.

In some embodiments, the readout circuit 210 comprises column readout circuit 214A-214C and analog-to-digital converters (ADC) 216A-216C. In some embodiments, each of the column readout circuit 214A-214C and each of the ADCs 216A-216C are electrically coupled to a respective column of pixels. For example, a column of pixels comprises pixels 202A, 202D, and 202G. In some embodiments, the column readout circuits 214A-214C are configured to receive signals from the columns. For example, a signal comprises a current generated based on a resistance of an electrically coupled pixel, a bias voltage at one node of the pixel, and a voltage at a second node of the pixel. In some embodiments, a column readout circuit comprises a capacitive trans-impedance amplifier (CTIA). In some embodiments, the ADCs 216A-216C are configured to receive outputs of column readout circuits 214A-214C and provide outputs 212A-212C, respective. In some embodiments, the outputs comprise digital representations of the signals received by the column readout circuits. In some embodiments, the readout circuit 210 comprises a readout integrated circuit (ROIC).

In some embodiments, the substrate 220 comprises a glass substrate. In some embodiments, the glass substrate comprises switches for coupling a pixel to a respective part of the readout circuit 210, and the switches are controlled by the row circuit 208. For example, the switches comprise thin-film transistors (TFT), and the row circuit is configured to provide a voltage for turning on a row of TFTs. When the row of TFTs turns on, a respective of row of pixels is electrically coupled to the readout circuit 210. In some embodiments, the switches comprise metal-oxide-semiconductor field-effect transistors (MOSFETs). In some embodiments, pixels 202A-202I, hinges 204A-204I, bias circuit 206, row circuit 208, and the switches are implemented on or over the substrate 220. In some embodiments, the substrate 220 is manufactured using a flat panel display process.

In some embodiments, because the substrate 220 is a glass substrate, metal layer thickness may be limited to 500 nm and a lower-resistance material (e.g., low-resistance copper) may not be available to reduce metal layer resistance. Therefore, column line resistance may be in a range of 1-100 kilohms. In some embodiments, the column voltage is held constant by the readout circuit 210 (e.g., using a CTIA), which measures a current flowing down the column line (from a selected pixel) instead of its voltage. By measuring the pixel current and holding the voltage constant, additional area and power consumption for implementing buffers to compensate for column line voltage drop may not be included, improving the performance of electronic device 200 on a glass substrate while reducing additional area and power cost.

In some embodiments, the readout circuit 210 is mounted on the glass substrate via a chip-on-glass (COG) process. In some embodiments, the readout circuit 210 is mounted on a flexible circuit, and the flexible circuit is attached to the glass substrate via a chip-on-flex (COF) process. The readout circuit 210, in some embodiments, generates 200-2000 mW of heat due to a number of signals being converted in parallel. The COF process may advantageously thermally isolate the readout circuit 210 from the glass substrate, reducing thermal stress gradients from a side of the electronic device 200 associated with the readout circuit. Furthermore, the COF process may allow a thicker conductive material (e.g., 1-10 μm) to electrically couple the readout circuit 210 to a host system, including power supplies, reducing voltage drops between the system power supplies and the readout circuit. In some embodiments, a metal plane is deposited on the substrate 220 (on a side opposite to the pixels) to reduce hotspot formation (from heat generated from the COF-attached readout circuit). In some embodiments, a metal layer (e.g., a metallized polymer) is inserted between the COF and the substrate 220 to further thermally decouple the readout circuit 210 from the substrate 220.

Although the electronic device 200 is described as illustrated in FIG. 2, it should be appreciated that the electronic device may be arranged and configured differently than illustrated. For example, the bias circuit and the row circuit may be placed at a different location of the device. As another example, the electronic device may comprise a different number of columns and a different number of row pixels. As another example, the readout circuit may comprise different components than described (e.g., the column readout circuit and the ADC may be integrated as one component). As another example, the pixels and hinges may be shaped, arranged, and sized differently than illustrated in FIG. 2.

It should also be appreciated that the components described with respect to FIG. 2 may comprise examples described with respect to the other Figures. It should also be appreciated that the components described with respect to FIG. 2 may be manufactured via examples described with respect to the other Figures. For example, the pixels, hinges, and circuits described with respect to the other Figures may be implemented on electronic device 200.

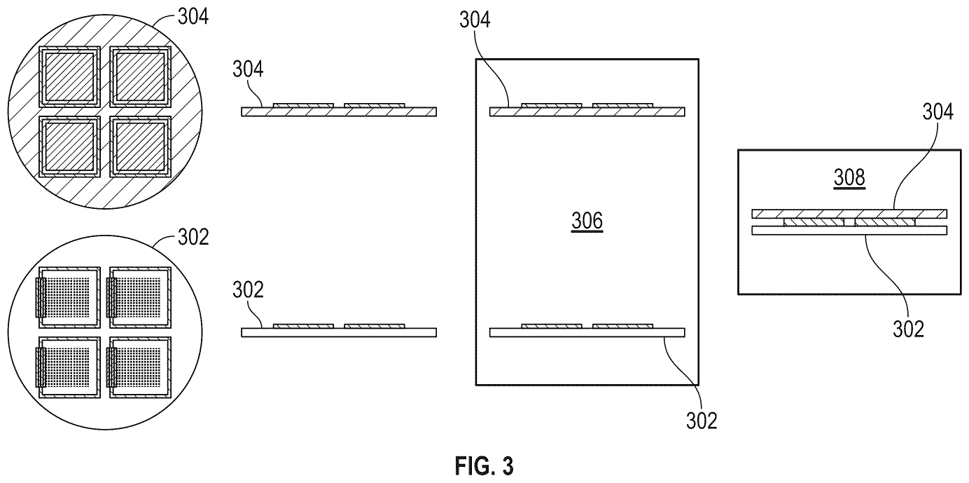

FIG. 3 illustrates an exemplary process for manufacturing an electronic device, in accordance with embodiments of this disclosure. In some embodiments, FIG. 3 illustrates a vacuum encapsulation process for a disclosed electronic device (e.g., electronic device 100, electronic device 200). For example, wafer 302 comprises sensor arrays such as uncooled microbolometer arrays. In some embodiments, a corresponding window wafer 304 is used to cap the devices (on wafer 302) using bonding agents such as solder. In some embodiments, the window wafer 304 is used to create lid 114. It should be appreciated that device wafer 302 may comprise one wafer or a plurality of wafers, and window wafer 304 may comprise one wafer or a plurality of wafers.

The procedure may be performed in a high vacuum environment. In some embodiments, the device is capped in a vacuum state, which is preserved by the encapsulation process. In some embodiments, the process comprises two thermal cycling events. Referencing FIG. 3, the first thermal cycling event comprises bake out (step 306) of surface and shallow volume trapped volatiles in both the device wafer 302 and window wafer 304. As illustrated, in some embodiments, bake out of the device wafer 302 and window wafer 304 is performed prior to bonding the two wafers.

The release etch process, prior to bake out, may leave behind volatile and non-volatile residue on the surface of the device wafer 302, but it may also expose other surfaces on the device wafer that can outgas from process steps previous to the release etch. The window wafer 304 may also likewise harbor outgassing sources, so both wafers may need to be baked during the bake out step 306. In some embodiments, during the bake out step 306, the temperature is ramped to a high temperature, in vacuum, that does not damage the device elements such as TFTs and MEMS structures and held for a sufficient length of time to desorb volatile species such as H, H₂, O₂, H₂O, N₂ and other molecules. For example, the temperature is 250 C to 300 C and the soak time is 15-30 minutes. In some instances, getter that can be patterned onto either or both device or/and window surfaces is used. These getters are activated at a high temperature. For example, the getter can be activated during the bake out step 306.

In some embodiments, after the bake out step 306, the window and device wafers are brought close together to align solder metals to metallized surfaces that can be wetted by the melting solder (step 308). The step 308 comprises the application of heat (e.g., the second thermal cycling event) for bonding the window and device wafers. In the case of eutectic alloys such as AuSn, the temperature may need to exceed 280 C. During this heating, impurities from the solder may outgas and increase the pressure inside the encapsulated cavity.

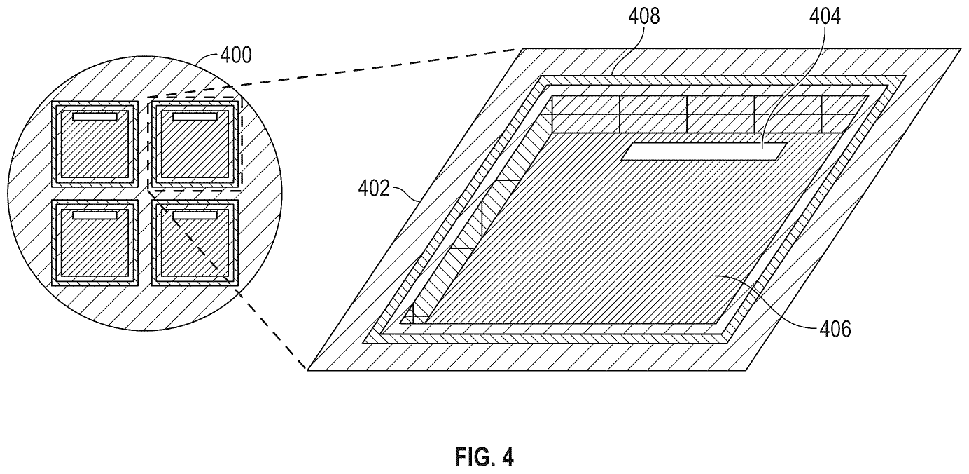

In some embodiments, a process comprising a second encapsulation step (e.g., using a window cap) as described with respect to FIGS. 4-6, is implemented on a single device package level or a wafer package level wherein multiple devices are encapsulated. An exemplary benefit is that the second encapsulation step can be performed at a lower temperature and can preclude the need for getters, which may be costly.

In some embodiments, an exemplary electronic device comprises microbolometers disposed on a glass substrate. The microbolometer pixels can be accessed through an array of column metal traces that couple to an externally supplied (e.g., not disposed on the glass substrate, away from the microbolometer array) readout circuit that cross with row metal traces that connect with on-glass row multiplexing circuits. As such, a plurality of electrical lines crosses the encapsulating bond lines (e.g., where the device wafer and window wafer are bonded). Eutectic metals such as Au/Sn (80/20) can planarize over topography introduced by the undercrossing metal lines (covered by passivating dielectrics that protect the metal lines). Glass frit bonding processes may also be used and in some cases, laser induced bonding (whether by locally melting or temporarily dissociating the glass, silicon, and passivating materials).

In some embodiments, a window 402 of window wafer 400 comprises an opening 404, in addition to the cavity 406 (e.g., for defining cavity 118), as illustrated in FIG. 4. In some embodiments, at the outside surface of the opening 404, a patterned metal pad 408 is placed around the opening 404 to e.g., aid solder wetting during its sealing step, where the solder is transported into the sealing region from its application point by wicking. In some embodiments, wicking comprises moving the solder from an application point to wet the metallized ring on the window and window gap. It should be appreciated that the size, geometry, and location of opening 404 illustrated in FIG. 4 are exemplary.

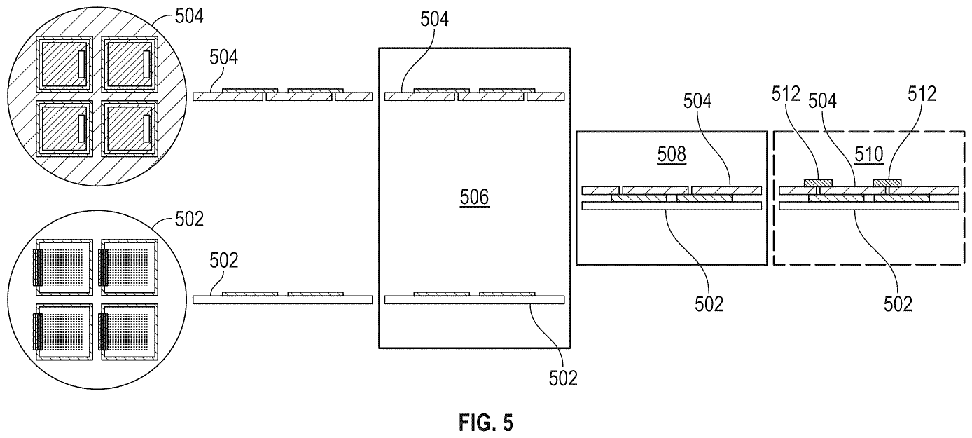

FIG. 5 illustrates an exemplary process of manufacturing an electronic device, in accordance with embodiments of this disclosure. In some embodiments, FIG. 5 illustrates a vacuum encapsulation process for a disclosed electronic device (e.g., electronic device 100, electronic device 200). For example, device wafer 502 comprises sensor arrays such as uncooled microbolometer arrays. In some embodiments, a corresponding window wafer 504 is used to cap the devices (on wafer 502) using bonding agents such as solder. In some embodiments, the window wafer 504 comprises one or more windows (e.g., window 402 comprising opening 404). In some embodiments, the window wafer 504 is used to create lid 114. It should be appreciated that device wafer 502 may comprise one wafer or a plurality of wafers, and window wafer 504 may comprise one wafer or a plurality of wafers.

In some embodiments, the bake out procedure described with respect to FIG. 3 is performed to device wafer 502 and window wafer 504 (step 506). Although FIG. 5 illustrates the capping of a single device, but it should be appreciated that the process described with respect to FIG. 5 may also be applicable at a wafer level. The bake out step 506 can be performed at e.g., 300C for 15-30 minutes.

In some embodiments, the seal between the device wafer 502 and window wafer 504 is performed at step 508. In some embodiments, the step 506 is not performed at high vacuum because the window opening may not allow encapsulation during this step. In some embodiments, this first seal provides the first amount of the sealing that surrounds the device periphery and planarizes over the undercrossing metal lines (e.g., as described with respect to FIG. 3).

In some embodiments, a second seal is performed at step 510. In some embodiments, the second seal comprises sealing the opening of the window wafer 504 (e.g., opening 402). In some embodiments, the opening is sealed using a window cap 512. In some embodiments, the second seal is performed via a lower temperature solder or is provided by a room temperature, locally generated heat source. In some embodiments, prior to the second seal, a bake out procedure is performed at a temperature that does not compromise the first seal, but is higher than the temperatures required for performing the second seal. For example, this bake out procedure is performed at 80 C to 400 C. In some embodiments, the second seal is configured to provide hermetic protection across the life of the device (e.g., 15 years), provide high vacuum (e.g., 10 mTorr or less), and operate over e.g., −40 C to +85 C range. In some embodiments, the first and second seals enable vacuum inside the cavity 118 of electronic device 100.

In some embodiments, the second seal comprises a window cap (e.g., a glass cap) configured to cover a window opening of a window wafer. For example, an electronic device, manufactured by the process described with respect to FIG. 5, comprises a glass device substrate, a silicon window which has an opening surrounded by a metallized area, and a glass cap is used to provide the second bond seal with an indium-based solder that wets the metal adhesion layer on the silicon, for example, beginning with the application point and wetting the metallized rings of the window and opposing lid. The silicon window and the glass cap may form a lid of the electronic device (e.g., lid 114).

In some embodiments, indium containing alloys, such as InSn, InAg, or In, are used as solder material for the second seal. Since the window opening is smaller than the device periphery, the solder needed may be less than what was used in the first seal. In some embodiments, the second seal is performed between a window opening comprising a metallized surface and the exterior surface of the window.

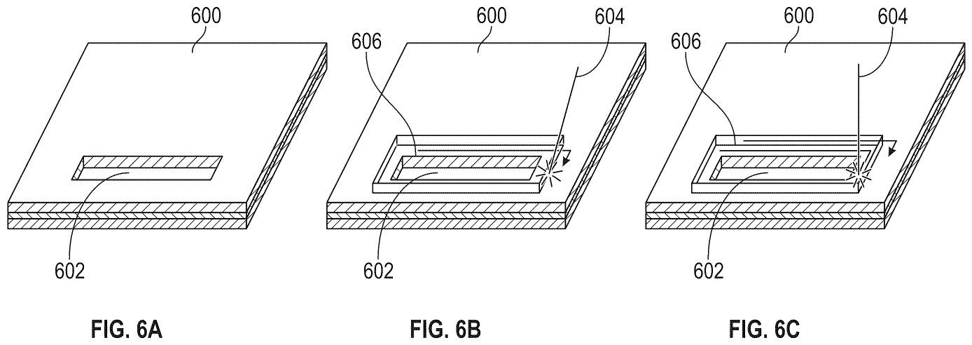

In some embodiments, a laser sealing technique is used to perform the second seal with or without intervening metal materials between the window cap 602 (e.g., glass, silicon) and the window 604. In some embodiments, the laser sealing step is performed in a vacuum environment. In some embodiments, the laser sealing step is performed at room temperature. FIG. 6A illustrates a window 600 comprising opening 602, and the opening 602 may be sealed via a laser sealing technique.

In embodiments not involving metal, as illustrated FIG. 6B, the edges of the window cap 606 can be selectively melted by the laser 604 (e.g., CO₂ laser at 10.6 μm is absorbed by a glass window cap) and thus adjoin the window cap 606 to the window surface and seal the open 602. In some embodiments, the laser wavelength is chosen to pass through the glass, to be absorbed by the window (e.g., a silicon window) which either melts or dissociates to bond with the opposing glass surface. For example, the laser wavelength is 400-980 nm.

In some embodiments, as illustrated in FIG. 6C, a laser wavelength is chosen, such that the laser 604 passes through the window cap material (e.g., 0.4-4 μm for a glass cap, 1.2-5 μm for a silicon cap) but is absorbed by the intervening metal layer 610 which melts and then cools to solidify and provide the encapsulating barrier for the second seal.

In some embodiments, a solder material is either plated or placed as a solder preform between the metallized surfaces of the device wafer and window wafer (as described with respect to FIGS. 3-6) being bonded together. In some embodiments, the two metallized surfaces are brought together in proximity (e.g., by asperities in the surfaces themselves, by bump features that can guarantee a repeatable and uniform separation) and solder is introduced at the boundaries outside the cavity. At the melting temperature, the metal surfaces wick the solder (e.g., by metal patterns on window, by metal patterns on glass substrate), and the bond can be realized.

In some embodiments, the window wafer comprises silicon. In some embodiments, the window wafer comprises germanium. In some instances, germanium may be required for larger arrays that require thicker windows to resist pressure induced bending. In some embodiments, thicker silicon windows may absorb more incoming LWIR radiation (compare to a thinner silicon window).

In some embodiments, the pixel gain (e.g., bolometer pixel gain) or responsivity is a function of the pixel design, materials used in the implementation, and the ambient pressure in the encapsulated cavity. The gain can be expressed as readout circuit counts (e.g., outputs 212A-212C) per absorbed power in the pixel. In some embodiments, a disclosed electronic device comprises an integrated pressure sensor, which may advantageously assist device sorting during manufacture, to assess and label the device quality, for example.

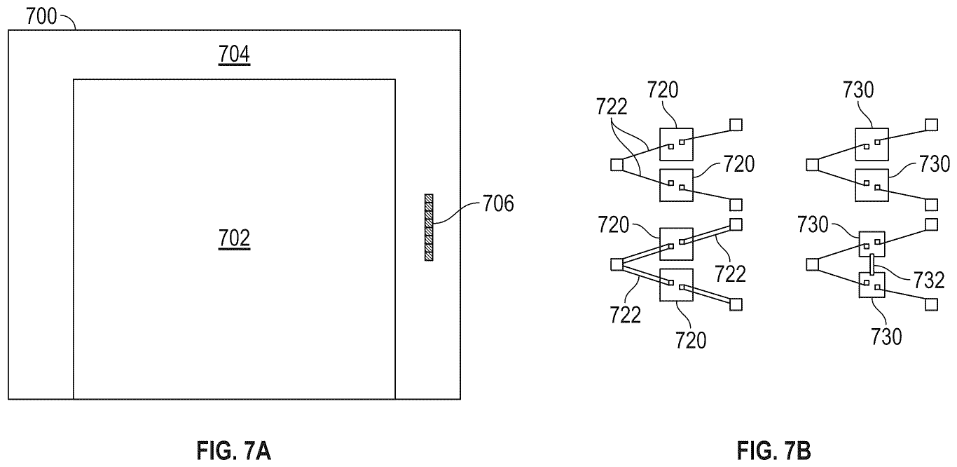

An exemplary sensor array 700 is shown in FIG. 7A. In some embodiments, the sensor array 700 is a sensor array of a disclosed electronic device (e.g., electronic device 100, electronic device 200) comprising pixels described with respect to the disclose electronic devices. In some embodiments, the sensor array 700 comprises an active area 702 that is surrounded by dummy pixel area 704, which are present to ensure uniformity of processing during the fabrication procedures. For example, the density of patterned features may change from the middle of the array toward the edges, so having additional dummy pixels to move the edge out further may be helpful (e.g., to reduce edge effects on active pixels).

In some embodiments, the pressure sensors 706 are positioned within the dummy pixel area 704. In some embodiments, the pressure sensors 706 comprise microbolometers (like the pixels in the active area 702 with full connections to readout circuit (e.g., readout circuit 210) and the row multiplexers to turn each sensor pixel on and off (e.g., row circuit 208).

The gain of the pressure sensors 706 can be evaluated by presenting blackbody radiation (e.g., at least two) to measure its gain. For example, two distinct temperatures of the blackbody may be used in sequence to measure the gain. The exemplary pixel designs shown to FIG. 7B illustrate two examples to implement pressure sensor pixels. For example, gain variation of pressure sensors 720 may be achieved by controlling hinges 722. As illustrated, when the hinges 722 are in a first configuration (e.g., first number of hinges supporting the pressure sensors), the gain is G₀, and when the hinges 722 are in a second configuration (e.g., second number of hinges supporting the pressure sensors), the gain is G₀/2. As another example, gain variation of pressure sensors 730 may be achieved by coupling the pressure sensors 730 (e.g., via connection 732). As illustrated, when the pressure sensors 730 are not coupled together, the gain is G₀, and when the pressure sensors 730 are coupled together, the gain is G₀/2.

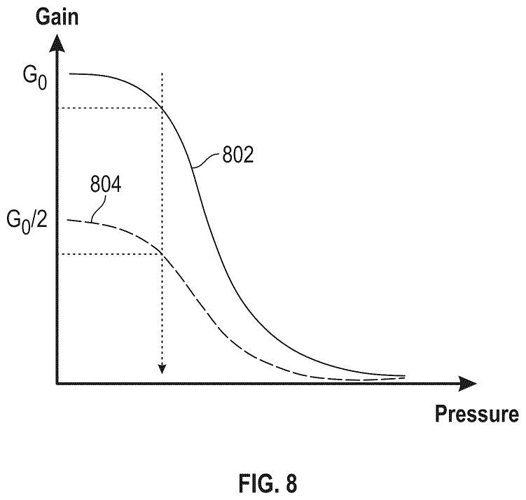

An exemplary gain as a function of the pressure (e.g., ambient pressure) is given by the illustrative curve in FIG. 8. When the gain of the pressure sensors is determined, the ambient pressure may be determined by the relationship between pressure and gain. In some embodiments, below an ambient threshold pressure value (as illustrated on the left of curves 802 and 804), the gain saturates at a maximum value that is determined by the pixel design (e.g., the different configurations shown in FIG. 7B) and the materials used to realize it.

As shown in FIG. 8, the gain saturates to a value determined by the pixel implementation. In some embodiments, the saturation value is set by varying the hinge thermal conductance, as shown in FIG. 7B, or coupling neighboring pixels while reducing the pixel area, as also shown in FIG. 7B. Returning to FIG. 7B, in the latter example, two neighboring pixels are coupled with a bridge (e.g., connection 732) between the pixel plates, but the total area presented by the two-pixel plates is the same as the regular pixel plate area. While the number of hinges connected to it has doubled, the thermal conductance is increased by a factor of two.

In some instances, a single measurement may yield the pressure value if the pixel gain value is known and fixed (e.g., from production run to run). In some instances, there are variations in the gain value. In some embodiments, a two-value measurement (or more with further varying gain values, such as 1, ½ and ⅓) is used to determine the gain value and the pressure. In some embodiments, to make this determination, the geometry within the set of sensors may need to be fabricated uniformly.

In some embodiments, to reduce outgassing, induction heating is used to selectively heat the solder preform (e.g., for bonding a disclosed electronic device). Other metal parts may also be heated up. However, the amount of metal (e.g., in volume) on the device may be small. Advantageously, non-metal parts like glass substrate and silicon cover may not heat up (and hence, outgassing may be reduced). In some embodiments, once the metal parts heat up and the AuSn preform melts, the cooling of the metal parts may be quick as the substrates that are in contact are in the room temperature and have high heat capacity. For example, heating of AuSn can be done in seconds by induction heating.

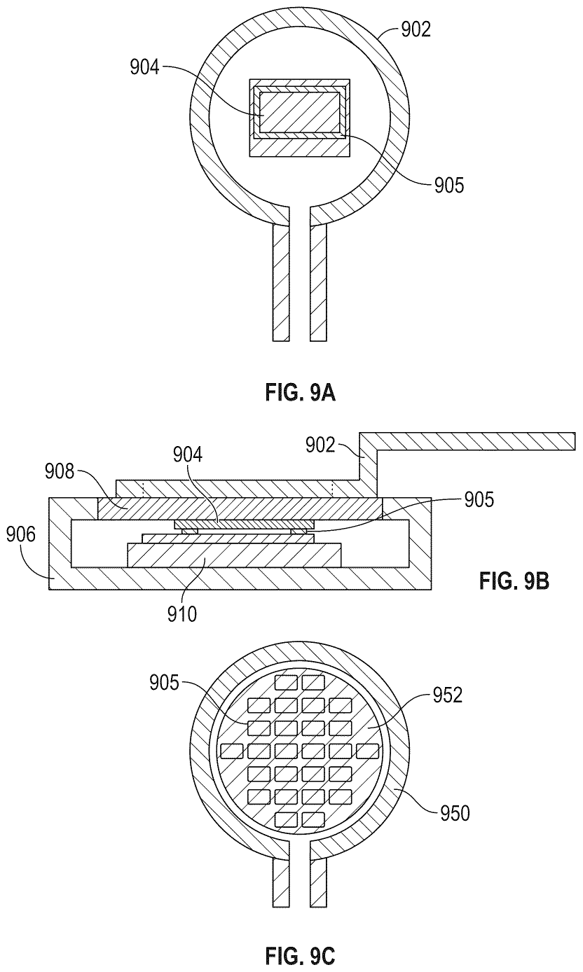

FIG. 9A shows the top view of exemplary device heating by induction heating. In some embodiments, induction heat head 902 is placed above the device 904 (e.g., a disclosed electronic device during manufacturing) to be sealed, with the device within the coil (e.g., centered) when viewed from the top. A power supply (not shown) applies current to the head coil of the induction heat head 902 and heats the metal parts in various parts of the device 904. Once the soldering metal 905 (e.g., AuSn) melts, then the current is turned off, and the parts cooled down. It should be appreciated that another solder material may be used.

In some embodiments, this application is for vacuum packaging, so the parts are in a vacuum chamber 906, as shown in FIG. 9B. Since induction heating can be done through glass surrounding of the vacuum chamber 906, the head is placed outside the vacuum chamber 906 above the vacuum chamber window 908 in some embodiments. In some embodiments, once the chamber is pumped down, the vertical translation stage 910 pushes the device assembly (e.g., substrate and cover sandwiching the sealing metal) up against the window 908, then the current is introduced to the induction heat head 902. Once the sealing metal melts and the seal established, the current is turned off. In some embodiments, this sealing process takes between a few seconds and few tens of seconds, thereby reducing the material outgassing (compare to a lengthier process without induction heating) since the device cavity is near room temperature because the induction heat head may only heat metallic portions of the device.

In some embodiments, where magnetic flux appears both inside and outside the coil of the induction head, the design of the coil and its surrounding vacuum chamber takes this magnetic flux into account and reduces the impact of this magnetic flux.

It should be appreciated that the induction heating method described with respect to FIGS. 9A-9C can be extended to wafer level (e.g., device-window wafer stack) sealing by appropriately designing the induction heading head. An example is shown in FIG. 9C. To increase uniformity of heating, the size of the induction head 950 may be larger than the wafer 952.

Noise in sensors that measure temperature changes via resistance (e.g., microbolometers) may include Johnson noise from resistors in the sensor, the chain of bias, amplification, and/or conversion circuitry, and may include 1/f noise in the sensor resistor and in the signal processing chain. Digital filters may address 2D spatial forms of noise (e.g., salt and pepper impulsive noise). 3D denoising filters utilizes correlations appearing in thermal imaging video between the time axis and the spatial dimensions, but a tradeoff may need to be made between data loss and noise filtering. With lower signal-to-noise ratio (SNR), spatial resolution and/or spatiotemporal artifact reduction may not be sufficient for some applications.

Although the 1/f noise present in the signal processing chain of the sensors can be suppressed by techniques such as correlated double sampling or instrument chopping, the 1/f noise that appears in the pixel resistor itself may not be cancelled using such techniques in some instances. The 1/f noise may appear as an addition to the Johnson noise that may be white in nature. The total noise present in the sensor output (for a particular pixel) may be expressed by the noise power spectral density:

$${S}_{n} ( f ) = K ( \frac{1}{f} + \frac{1}{{f}_{0}} ) ,$$

where K is a constant, f is the frequency, and f₀ is the frequency where the 1/f noise power density is equal to that of the white noise component (e.g., Johnson noise).

The 1/f noise spectrum may be unbounded at DC. Singularity at f=0 may be avoided by choosing a low frequency limit that corresponds to the longest time scale of interest. For example, for bolometers, this can be df=0.1 Hz corresponding to an epoch of 10 seconds. At a frame rate of 30 Hz, this is equivalent to 300 frames of video. The amount of noise present in a particular pixel output (e.g., expressed as digital counts, expressed as amps of current, other physical variable being measured) may be given by the noise power integrated within the sampling window.

In some embodiments of a raster scanned array, each row is sampled by a short window whose duration is determined by the video frame update rate fᵥ and the number of rows in the sensor array, M. The window duration may be given by

$$T = \frac{1}{M {f}_{v}}$$

For M=480 (e.g., VGA number of rows) and fᵥ=30 Hz, T=69.4 μsec. The power transfer function of this window function may be given by

$${\vert H ( f ) \vert}^{2} = \frac{{sin}^{2} ( π fT )}{{( π fT )}^{2}}$$

The total noise energy may be given by

$${N}_{1} = {\int }_{δ f}^{∞} K ( \frac{1}{f} + \frac{1}{{f}_{0}} ) \frac{{sin}^{2} ( π fT )}{{( π fT )}^{2}} d f \approx {\int }_{δ f}^{\frac{1}{T}} K ( \frac{1}{f} + \frac{1}{{f}_{0}} ) d f = K [ ln ( \frac{1}{δ fT} ) + \frac{1}{{f}_{0} T} ]$$

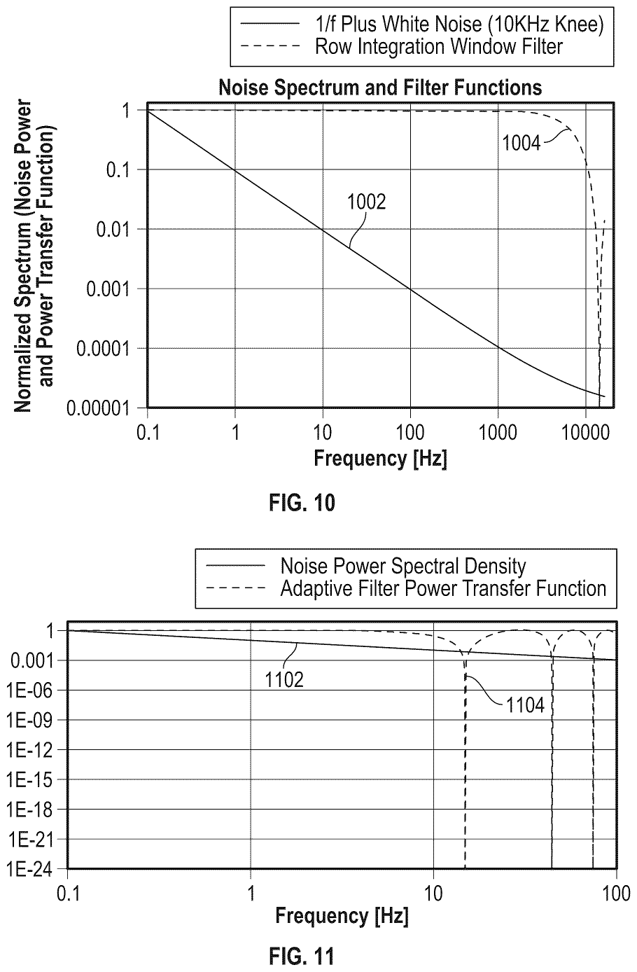

Examples of the noise power spectrum and the main lobe of the row integration window transfer function (curve 1004) (e.g., power transfer function) are illustrated in FIG. 10. As illustrated, the 1/f (curve 1002) and white noise crossover point is set at f₀=10 KHz, and the noise spectrum is normalized to the density at df=0.1 Hz.

In some embodiments, the values of a particular pixel from two frames (e.g., consecutive frames) are averaged, adding the past pixel value to the current pixel value, and the averaged value replaces the current pixel value. The averaging allows the video frame rate to be maintained while noise can be reduced, advantageously increasing SNR.

In some embodiments, prior to performing this averaging step to replace the current pixel output, a condition that the current pixel value is not too different (e.g., difference within a threshold value) from the immediate past (e.g., within previous threshold number of frames, previous frame) is satisfied. That is, the two frames (e.g., consecutive frames) are averaged and used for further processing (e.g., for generating a sensor image) in accordance with a determination that a difference between a past pixel value and a current pixel value (e.g., readout values of one of pixels 202A-202I between two consecutive readouts) are lower than a threshold value. For example, the threshold value is a difference within the smallest difference that can be displayed without a noticeable performance difference. As an example, a display can display 6 to 8 bits of greyscale so differences at the level may not be too different and can be averaged. The two frames are not averaged, and the current pixel value is used for further processing in accordance with a determination that a difference between the past pixel value and the current pixel value are not lower than the threshold value.

For example, the difference between the past pixel value and the current pixel value are lower than a threshold value when the pixel is derived from an object that is not changing in time. Such patches in the thermal image may exhibit fluctuations in time due to the 1/f and Johnson noise embedded in each output.

In some embodiments, since the camera comprising the sensors may be characterized by parameters such as Noise Equivalent Temperature Difference (NETD), a threshold value based on this, in some embodiments, may be used to compare the current pixel output from its immediate past (frame) value. Such a threshold value is sampled during the camera startup routing, for example. As another example, it can be determined during factory calibration.

In some embodiments, if the current pixel value differs from its past value by an NETD amount greater than this NETD threshold, the current pixel value is kept as the output. Otherwise, it is replaced by the average of the current value and its past value.

In some embodiments, if the pixel value does not change (e.g., does not change beyond the threshold value) over many frames (e.g., more than two consecutive frames), the averaging process continues with integration, further reducing the amount of noise that may remain after the averaging process. If two frames are averaged for a given pixel, the total noise energy may be given approximately by

$${N}_{2} \approx {\int }_{δ f}^{\frac{1}{T}} K ( \frac{1}{f} + \frac{1}{{f}_{0}} ) {cos}^{2} ( π f M T ) d f \approx \frac{K}{2} [ ln [ \frac{1}{δ fT} ] + \frac{1}{{f}_{0} T} ]$$

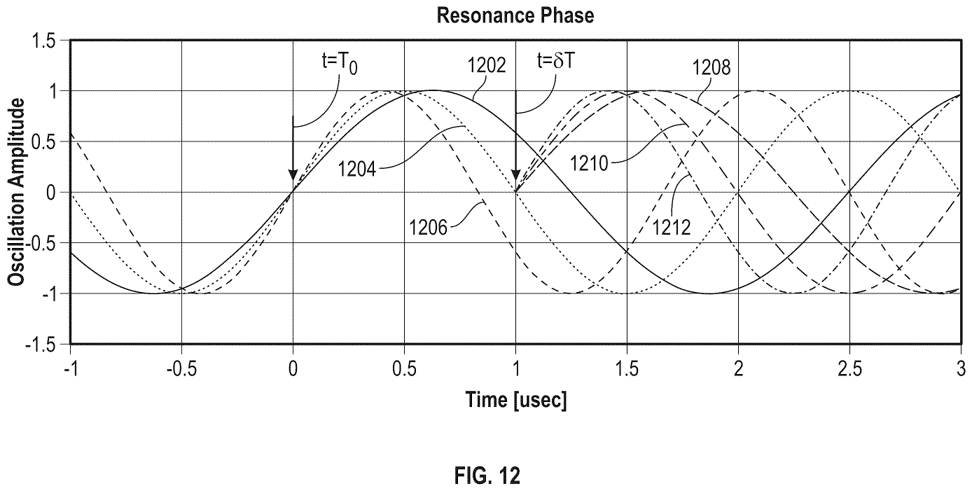

In some embodiments, the process of averaging two frames advantageously yields a 50% lower noise energy. In some embodiments, averaging L frames advantageously yields a noise energy that is 1/L of the single frame noise energy. FIG. 11 illustrates an exemplary noise power spectral density 1102 and an exemplary power transfer function 1104 of a disclosed two-frame averaging process.

This disclosed method may be advantageously different from denoising algorithms that may be set up to process noisy images in the presence of e.g., impulsive salt and pepper noise. When these noises are isolated, high energy “spikes” may be smoothed out (by the denoising algorithm) by median or median-like replacement functions based on comparison with a local neighborhood of pixels where the neighborhood can be spatial or spatio-temporal in the case of 3D noise. In some embodiments, elimination of sudden spikes that may appear from frame to frame in a given pixel since apriori is avoided (e.g., because it may be difficult to determine whether the spikes comprise a signal or noise). Since microbolometers may be characterized with metrics such as NETD, the conditional averaging methods disclosed herein may be predicated on the new pixel value being sufficiently close to the previous pixel value, to advantageously be within the NETD or comparable metric.

In some embodiments, the pixel difference condition (e.g., the above-described threshold) is determined at factory calibration or during camera startup. For example, the shutter of the camera may be closed, and the pixel value captured for J frames. The temporal standard deviation of a pixel over the J frames can be computed and used as the threshold condition for the averaging process, with the value unique for each pixel. The values may be stored in a lookup table of an associated device (e.g., memory of the camera). In some embodiments, a single threshold value averaged over an entire frame of pixels is used as a global threshold value. For example, more than two frames are averaged to determine if the threshold condition is met appropriately (e.g., the pixel difference from frame to frame is less than that of the threshold value).

In some embodiments, the resonance frequency of a system (e.g., microbolometer system, electronic device 100, electronic device 200) is around 500 KHz for embodiment comprising geometries ranging from 12 μm to 24 μm in pitch and sensor thicknesses associated with 30 Hz frame update rates. The resonance frequency is given by:

$${f}_{0} = \frac{1}{2 π} \sqrt{\frac{K}{m}}$$

where K is the stiffness and m is the pixel mass. In some embodiments, a sensor pixel is supported by a hinge (e.g., hinge 204A-204I). In some embodiments, hinge widths may have variations across a given sensor system. If the hinge widths vary by 50%, the resonance frequency may vary by 30% since the mass may be uniform, as may be other parameters such as the residual stress of the hinges.

Taking 500 KHz as an exemplary mean resonance frequency, the resonance frequency may vary from 400 to 600 KHz in a panel due to this variation. If each resonance frequency is associated with a higher Q (e.g., slower decay for associated oscillations) due to vacuum (e.g., in cavity 118), then it may be possible for repeated excitations at the 30 Hz frequency (e.g., each row of sensors of e.g., electronic device 200 is readout at 30 Hz) to cause instability because the oscillation may not decay quickly enough.

For example, if Q=10,000 (e.g., in electronic devices (e.g., electronic device 100, electronic device 200) packaged in high vacuum), then the resonant decay may be slow on the scale of the frame time interview. The impulse response of the oscillation may decay with a time constant equal to

$$\frac{Q}{π {f}_{0}} = \frac{10 , 000}{π400 KHz} \approx 8 msec .$$

This may be shorter than the 33 msec period of the pixel bias excitation, but the oscillation energy when the second excitation arrives may not be zero. With repeated excitation, oscillation may build up to the point of instability. For the 30 Hz frame rate, each pixel's bias voltage may switch on momentarily (for 480 rows−1/(480*30)−625/9 μsec) every 1/30 sec. For two successive excitation events to be in phase, the resonance frequency may be an integer multiple of 30 Hz (e.g., harmonics of 30 Hz). In the range 400 to 600 KHz, such frequencies may be 30*J where J=13,334 to 20,000. Build up may not require an exact integer multiple but frequencies that lead to an opposite phase relationship (e.g., f₀=13334.5*30 Hz) may prevent oscillation build up.

In some embodiments, instead of a fixed periodic frame update (e.g., for reading out electronic device 100, electronic device 200), if two or more different update intervals are allowed in such a way that the average frame rate is a desired value, oscillation build up may be prevented. For example, the first interval is T₀ ( 1/30 sec) for the array during a first time period and the second update interval is T₀+dT₁ for the array during a second time period (different from the first time period), and this sequence is repeated. For the first time period, pixels that resonate at frequencies J/To may lead to oscillation build up. dT may be chosen such that the excitation at t=T₀+dT is out of phase with the new excitation for the mid-frequency 500 KHz (such that an oscillation frequency is not a multiple of the second frequency 1/(T₀+dT), such as a harmonic of the second frequency). For example, dT is 1 μsec.

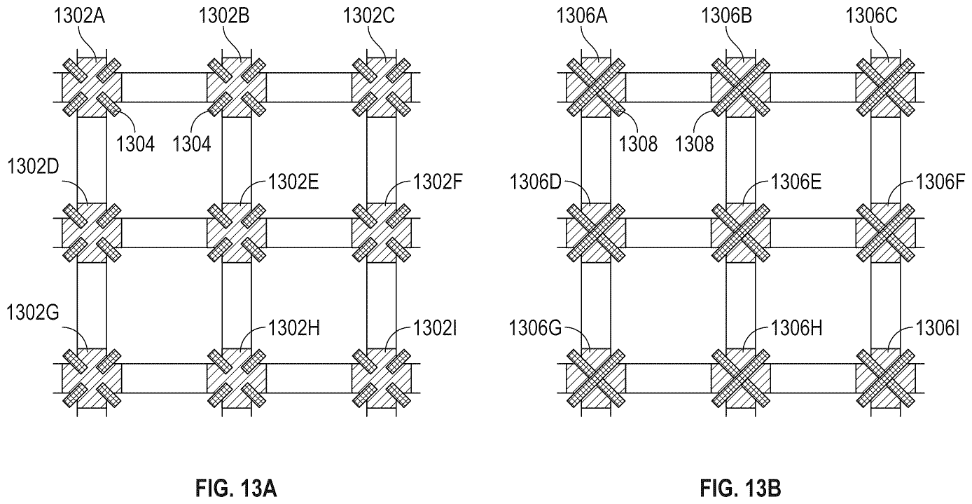

As illustrated in FIG. 12, oscillations for 400 to 600 KHz are out of phase and may help suppress resonant build up. If the new excitation starts at t=dT, the new oscillations (oscillations 1208, 1210, and 1212) depicted by the dotted lines and the oscillation from the previous frame may be out of phase. It should be appreciated that the amplitude of oscillations (associated with a current frame and previous frames) may be different due to decay, that some oscillations from previous frames are not shown here (e.g., oscillations from some previous frames have decayed), and that the oscillation frequencies are exemplary.

As illustrated, exemplary oscillations 1202, 1204, and 1206 are respectively 400 KHz, 500 KHz, and 600 KHz oscillations that are associated with exemplary variations in excitations caused by the T₀ update interval, and exemplary oscillations 1208, 1210, and 1212 are respectively 400 KHz, 500 KHz, and 600 KHz oscillations that are associated with exemplary variations in excitations caused by the T₀+dT update interval. Adding more variations in frame intervals may restrict the number of resonance frequencies that are close to oscillation build up.

In some embodiments, the refresh rates correspond to a frequency of readout of a group of sensors. For example, a first frequency of reading out a group of sensors (e.g., a sensor array disclosed herein) is 30 Hz during a first time period, and a second frequency of reading out the group of pixels is 29.999 Hz (i.e., ( 1/30 Hz+1 μsec)⁻¹) during a second time period (e.g., after the first time period). The sequence of the first time period and the second time period may be repeated. The length of the first time period may be determined such that oscillations caused by readout during the first time period are below a first threshold amplitude. The length of the second time period may be determined to allow the oscillations (caused by readout during the first time period) to decay below a second threshold amplitude at the end of the second time period. In some embodiments, an average of the different readout frequencies (e.g., the first frequency, the second frequency) is a desired readout frequency of an associated system (e.g., camera). For example, the average is 30 Hz.

In some embodiments, the different readout frequencies are achieved by configuring the row circuitry 208 to switch the rows of sensors at the first frequency (e.g., 1/To) during the first time period and at the second frequency (e.g., 1/(T₀+dT)) during the second time period. In some embodiments, phantom rows are used to implement the variable frame intervals. For example, the row circuit 208 is configured to switch successive row outputs at one interval, and during a period of slower readout frequency, one or more outputs of the row circuit 208 not connected to sensors are driven, such that a slower readout frequency is achieved (compared to the row circuit only driving rows connected to the circuit when the readout frequency is faster). In some embodiments, one or more of the dT, the first time period, and the second time period are determined by a controller or processor of the electronic device, based on the device's frame rate and/or oscillation frequencies, as described above.

It should be appreciated that more than two frequencies may be used for readout to reduce oscillation build up. It should also be appreciated that the first time period associated with the first frequency and the second time period associated with second frequency may not be fixed. For example, the first time period and/or the second time period may be updated based on effects of oscillation on the device. As an example, if the effect of oscillation is determined to be reduced, the first time period may update to be longer and/or the second time period may update to be shorter, such that less out of phase oscillations are generated; if the effect of oscillation is determined to be increased, the first time period may update to be shorter and/or the second time period may update to be longer, such that more out of phase oscillations are generated.

As the ambient pressure is reduced (e.g., for creating a vacuum in electronic device 100, electronic device 200), Q associated with the device's resonance may increase until air damping is a less dominant source of friction in the system. Q may saturate as a smaller dissipative effect takes over, for example, inelastic behavior in the mechanical system. In some embodiments, inelastic behavior is introduced to electronic device 100 and/or electronic device 200 to reduce Q by causing it to saturate.

In some embodiments, the hinge (e.g., hinges 204A-204I) has two components-one providing an electrical connection and the other providing mechanical rigidity. In some embodiments, an additional layer is added, and the additional layer is composed of a soft polymeric material with high thermal stability such as polyimide or a soft inorganic material such as lead, tin, silicon dioxide, or nitride. In some embodiments, an organic material may be encased in the inorganic mechanical material, and the organic material may advantageously reduce outgassing.

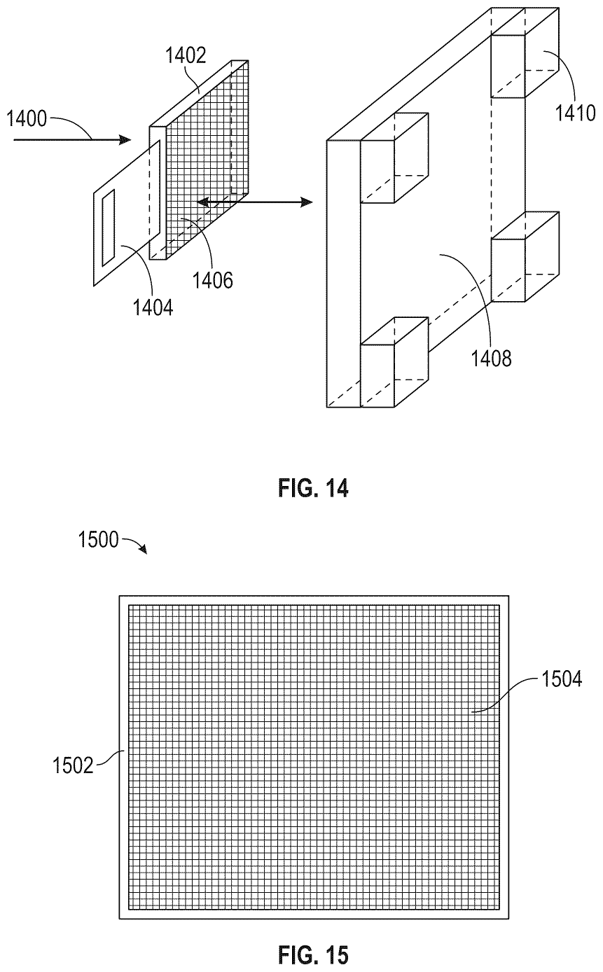

In some embodiments, polyimide residue, resulted from inorganic dispersants in the polyimide added to promote surface adhesion, may be used to reduce Q of device or system resonance. For example, after the release etch using oxygen plasma, such sacrificial materials may leave behind a network of residue filaments (e.g., an ultra-low-density network) that connect to surfaces around it. In some embodiments, the residue network is accomplished by depositing a polyimide on top of a fully processed but unreleased microbolometer array (e.g., electronic device 200) and patterning the polyimide to form bridge patterns that connect the corners of the pixel to anchoring structure below the pixels (e.g., pixels 202A-202I), as illustrated in examples in FIGS. 13A and 13B.

After the patterning step, the polyimide layers may be released in one oxygen plasma etch step, leaving behind a patterned network of residue filaments 1304 that connect the pixels 1302A-1302I (e.g., pixels 202A-202I) corners to the substrate (e.g., substrate 220) below, as illustrated in the example in FIG. 13A. In some embodiments, residue filaments 1308 of the pixels 1306A-1306I corners may attach to one another, bypassing the connection to the structures (e.g., the substrate) below, as illustrated in the example in FIG. 13B. In some embodiments, the residue filaments 1304 and 1308 are etched and patterned (e.g., after deposition) to form the patterns as described with respect to FIGS. 13A and 13B. The residue filaments 1304 and 1308 advantageously reduce the mechanical Q of the resonance by causing saturation of Q, as explained above.

In some embodiments, the oscillation decay time constant is proportional to the ratio Q/f₀. Therefore, f₀ may be increased to speed up decay time and reduce oscillation build up by, for example, mass reduction and/or increase in the resonant frequency.

In some embodiments, the sensor layer (e.g., a layer of pixels 202A-202I) is thinned to decrease total mass, which may lead to resonant frequency increase and reduce oscillation build up. For example, the sensor layer is thinned by 50 to 300 nm. In some embodiments, the pixels (e.g., pixels 202A-202I) comprise holes (e.g., etched holes, drilled holes) to decrease the overall mass, which may lead to resonant frequency increase and reduce oscillation build up. In some embodiments, the holes are smaller than a wavelength (e.g., LWIR) that an associated pixel is configured to absorb. For example, the holes are smaller than a quarter of this wavelength or less. In some embodiments, the resonant frequency is increased (to reduce oscillation build up) by increasing the stiffness of the hinge (e.g., hinges 204A-204I). This can be achieved by, for example, increasing the residual stress of the mechanical layer (e.g., using silicon dioxide or nitride) associated with the hinges.

In some embodiments, an electronic device (e.g., electronic device 100, electronic device 200) is designed to separate the heat producing readout integrated circuit (e.g., readout circuit 210, readout circuit 1404) from the sensor array. In some embodiments, the readout integrated circuit and sensor array are fabricated on separate substrates and connected through a low thermal conductance and plastic-backed flexible connector.

In some instances, temperature distribution across the sensor array may affect the uniformity of the pixel array response (e.g., offset variations between different pixels). In some instances, signals being transduced on a given pixel from optical (e.g., LWIR) radiation 1400 input are in the mK range, so a nonuniformity across the substrate (e.g., caused by different temperatures across the sensor array) can transfer onto the pixel array response in the form of offset variations.

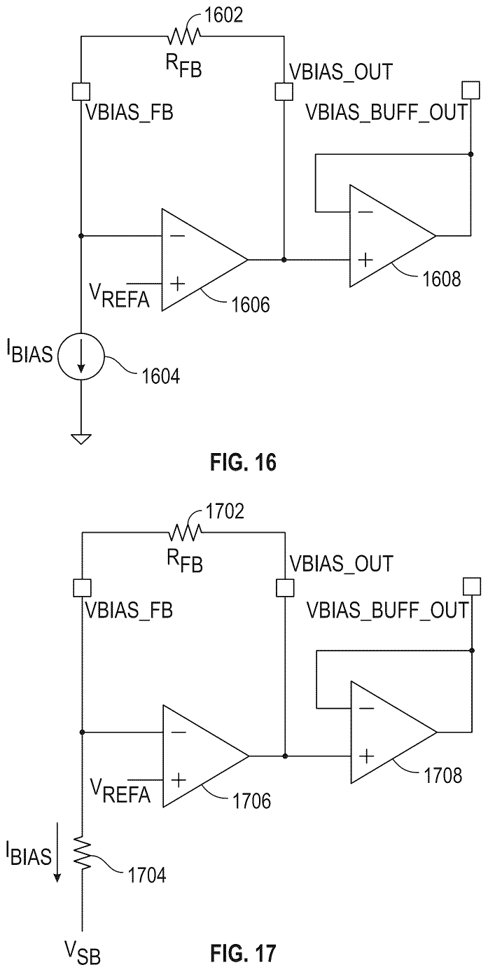

In some embodiments, to increase the uniformity of heat distribution, the glass substrate 1402 (e.g., substrate 112, substrate 220) is coupled to metallized backing 1406, as illustrated in FIG. 14. In some embodiments, the backing 1406 comprises sputtered metal such as aluminum, molybdenum, and/or titanium. In some embodiments, the substrate 1402 is attached to the backing 1406 via soldering. In some embodiments, the material of the backing 1406 is the base for a solder-based attachment process. In some embodiments, the arrangement described with respect to FIG. 14 improves the spatial uniformity of sensors on substrate 1402 (e.g., microbolometers) by providing a metal backing that is thermally isolated from a camera body.

In some embodiments, the support plate 1408 to which the substrate 1402 and readout circuit 1404 mount is a copper plate that can have a plastic or dielectric base (e.g., in the form of PCB, injection molded polycarbonate or similar polymer). In some embodiments, the electronic device is part of a camera (e.g., thermal camera), and the support plate 1408 in turn is secured to camera housing through attachments 1410. In some embodiments, the attachments 1410 have a low thermal conductance to thermally isolate the sensor of the electronic device from the surrounding environment.

In some embodiments, the device glass substrate (e.g., substrate 112, substrate 220, substrate 1402), which can have a 0.5 mm thickness, is fortified to withstand bowing after vacuum encapsulation. In some embodiments, a silicon wafer is attached to the glass substrate in wafer form by soldering, low outgassing epoxy, or glass-to-silicon direct bonding techniques such as anodic bonding prior to device release etch for this fortification. In some embodiments, the silicon is advantageously coefficient of thermal expansion (CTE) matched to glass and provides a good thermal conduction path to the sensor support platform.

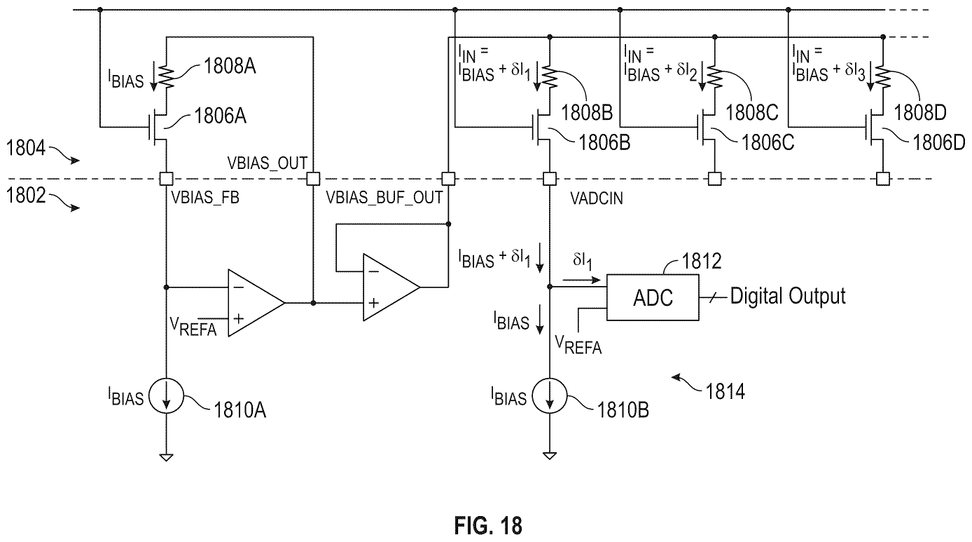

In some embodiments, the substrate (e.g., substrate 112, substrate 220, substrate 1500) temperature can be measured periodically. The periodic measurements may advantageously allow correction of the gain and offset of the pixels, as influenced by the environment, based on the temperature measurements. FIG. 15 describes an example configuration and methods for measuring the sensor panel temperature distribution by thermometers (e.g., sensors in boundary 1502) built on the periphery to aid the non-uniform correction.

In some embodiments, separating the heat generating readout integrated circuit from the sensor panel (e.g., as described with respect to FIG. 14) enables an accurate measurement of the sensor panel by measuring the temperature profile of the boundary 1502 of the sensor panel 1504. In some embodiments, the sensor panel 1504 comprises pixels 120 and/or pixels 202A-202I.

Since the sensor panel itself may generate less heat within the sensing areas, knowledge of the temperature distribution on the sensor array boundary can be used to estimate the temperature profile throughout the sensor area. In some embodiments, resistors having a defined TCR are formed on the substrate of sensor panel 1504 (e.g., in a linear pixelated format) following the boundary 1502 of the sensor array 1504 to be characterized, as illustrated in FIG. 15.

In some embodiments, the resistors on the boundary 1502 comprise microbolometer pixels that have been thermally shorted to the substrate. For example, mechanically collapsed pixels sacrificial material in these microbolometer pixels is absent in the fabrication procedure, or the sacrificial material is not removed during the release etch. In some embodiments, the resistors can be bigger in size compared to a pixel of the sensor array 1504. In some embodiments, the pixel used for measuring temperature in the boundary 1502 may be bigger than the pixel of the sensor array 1504, but have a same aspect ratio, such that the resistances of the two pixels are the same. This approach may be called the Big Pixel.

In either case, in some embodiments, the resistance value tracks the temperature of the underlying substrate and is readout along with the values from the sensor array 1504. In some embodiments, two columns and two rows (or integer multiples thereof if multiple sampling is desired at each location) of the readout comprise the temperature measurement data.

These thermally shorted resistors may or may not be optically sensitive (e.g., depending on the level of infrared radiation falling on the sensor). In some embodiments, the resistors are not optically sensitive (e.g., for some operating regimes), which advantageously precludes a need for optical masking the resistors to isolate them from the incoming radiation and/or the ambient.

FIG. 16 illustrates an exemplary bias voltage generator of a readout circuit disclosed herein. In some embodiments, the readout circuit (e.g., readout circuit 210) provides the bias voltage (VBIAS_BUFF_OUT) for each row of pixels, with the same bias voltage applied to all pixels in the row, by using a bias current, I_{BIAS}, determined by a current source circuit 1604 on the readout circuit and replicating that in a reference sensor on the glass substrate called R_{FB}. In some embodiments, the resistance value R_{FB} depends on temperature sensed by reference resistor 1602, and changes in R_{FB} would cause VBIAS_BUFF_OUT to change, allowing the bias voltage provided to the active sensors to track a reference temperature of the electronic device. In some embodiments, the current generator 1604 may be programmable, allowing the bias current I_{BIAS} to be adjusted.

The circuit shown in FIG. 16 generates a bias voltage, V_{BIAS}, at the node V_{BIAS}_OUT, which may be given approximately by:

V_{BIAS}=V_{REFA}+I_{BIAS}·R_{FB}

Where the amplifier 1606 (e.g., operational amplifier) is assumed to be ideal, that is, to have negligible input offset and very high gain. In some embodiments, the bias voltage, V_{BIAS}, is buffered at VBIAS_BUFF_OUT by the unity gain voltage buffer 1608, with the voltage buffer 1608 designed to deliver sufficient current to drive all pixels in a row with negligible disturbance in the output voltage VBIAS_BUFF_OUT.

In some embodiments, the I_{BIAS} current generator is implemented as a low TCR resistor 1704 on the readout circuit that is connected between the feedback node VBIAS_FB and a set voltage V_{SB}, as illustrated in FIG. 17. The bias current may be:

$${I}_{BIAS} = \frac{{V}_{R E F A} - {V}_{S B}}{{R}_{BIAS}}$$

where R_{BIAS} is the bias resistor 1704. In some embodiments, V_{SB} may be the ground voltage. In some embodiments, V_{SB} may be set by a programmable voltage source. In some embodiments, the feedback resistor 1702, R_{FB}, is a reference sensor on the glass and may serves a similar function as reference sensor 1602 in FIG. 16.

In some embodiments, the resistor 1602 (or resistor 1702) comprises a blind bolometer pixel (e.g., a bolometer pixel isolated from incoming radiation and/or the ambient), which may lead to some 1/f noise appearing on V_{BIAS}, in addition to its Johnson noise contribution. These, along with the difference (e.g., manufacturing variations, variation due to locations) between the resistor values R_{FB} and that of the pixel R_{PIX} may cause row-to-row non-uniformity that may generate row noise. In some embodiments, the resistor 1602 (or resistor 1702) comprises a Big Pixel (e.g., the pixel associated with resistor 1602 is a bigger pixel than a pixel associated with active pixel R_{PIX}, but has a same aspect ratio, such that the resistances of the pixels are the same), which may reduce 1/f noise and improve bias stability, leading to lower row noise.

In some embodiments, the bias voltage (V_{BIAS}=VBIAS_BUFF_OUT) is used to readout pixels from a given row as explained by the example illustrated in FIG. 18. In some embodiments, FIG. 18 illustrates readout circuit 1802 and panel 1804. In some embodiments, the readout circuit 1802 is part of a readout circuit disclosed herein. In some embodiments, the panel 1804 comprises TFT switches 1806A-1806D (e.g., switches of electronic device 200 controlled by row circuit 208), which are switches for selectively coupling a row of pixels (e.g., a row of pixels disclosed herein) to readout circuit 1802 while other rows are decoupled. As illustrated, switches 1806B-1806D are configured to couple a respective active pixel to a channel input of the readout circuit 1802. In some embodiments, the row of pixels includes reference pixel 1808A and active pixels 1808B-1808D. In some embodiments, one terminal of the active pixels is coupled to VBIAS_BUFF_OUT for receiving a bias voltage generated by bias voltage generator (e.g., as described with respect to FIGS. 16 and 17) of the readout circuit 1802. In some embodiments, the readout circuit 1802 comprises ADC input stage 1814, including current-sensing ADC 1812, which may be one of ADCs 216A-216C.

In some embodiments, the bias current in the input stage 1814 generated by the current source 1810B is the same as the bias current in the bias voltage generator set by current source 1810A. In some embodiments, the ADC input voltage VADCIN is referenced to the same common reference voltage V_{REFA} used in the bias voltage generator, and the ADC may have a negligible input voltage offset so that VADCIN is equal V_{REFA}. The current from the pixel 1808B labeled as I_{IN} may be given by:

$$\begin{matrix}{I}_{IN} = \frac{{V}_{BIAS} - V ADCIN}{{R}_{PIX}} \\ = \frac{{V}_{R E F A} + {I}_{BIAS} \cdot {R}_{F B} - {V}_{R E F A}}{{R}_{PIX}} \\ = {I}_{BIAS} \cdot ( \frac{{R}_{F B}}{{R}_{PIX}} )\end{matrix}$$

R_{PIX} is the bolometer resistance of pixel 1808B.

In some embodiments, the resistor values in the above expression have the same activation energy (e.g., TCR), but differ in the nominal values. For example, R_{PIX} may vary due to the temperature change arising from the absorbed optical power P_{O} isolated by the thermal conductance G_{TH}.

$$\begin{matrix}{R}_{PIX} = {R}_{PIX 0} + Δ R \\ = {R}_{PIX 0} \cdot ( 1 + \frac{Δ R}{{R}_{PIX 0}} ) \\ \approx {R}_{PIX 0} \cdot ( 1 + \frac{1}{{R}_{PIX 0}} \cdot \frac{d {R}_{PIX}}{d T} \cdot Δ T ) \\ = {R}_{PIX 0} \cdot ( 1 + \frac{1}{{R}_{PIX 0}} \cdot \frac{d {R}_{PIX}}{d T} \cdot \frac{{P}_{0}}{{G}_{T H}} )\end{matrix}$$

$$And$$

$$\begin{matrix}δ I = {I}_{IN} - {I}_{BIAS} \\ = {I}_{BIAS} \cdot ( \frac{{R}_{F B}}{{R}_{PIX}} - 1 ) \\ \approx {I}_{BIAS} \cdot ( \frac{{R}_{F B}}{{R}_{PIX 0}} ( 1 - \frac{1}{{R}_{PIX 0}} \cdot \frac{d {R}_{PIX}}{d T} \cdot \frac{{P}_{0}}{{G}_{T H}} ) - 1 ) \\ = {I}_{BIAS} \cdot ( \frac{{R}_{F B}}{{R}_{PIX 0}} ( 1 - TCR \cdot \frac{{P}_{0}}{{G}_{T H}} ) - 1 )\end{matrix}$$

Where the change in pixel resistance due to the absorbed optical power is small in some embodiments.

In some embodiments, assumptions for this calculation may be made, such as the vacuum being sufficiently high to neglect thermal conduction due to gas and the pixel emissivity is unity. In this example, both R_{FB} and R_{PIX0} are temperature dependent, as is TCR. The gain and offset are given by:

$$δ I = gain \cdot {P}_{0} + offset$$

$$gain = - {I}_{BIAS} \cdot ( \frac{{R}_{F B}}{{R}_{PIX 0}} \cdot \frac{T C R}{{G}_{T H}} )$$

$$offset = {1}_{BIAS} \cdot ( \frac{{R}_{F B}}{{R}_{PIX 0}} - 1 )$$

In this example, the overall dependences of both gain and offset on temperature are similar. The direct dependence of pixel and reference resistor values on temperature are cancelled but a more slowly varying dependence on temperature remains through the TCR and I_{BIAS} dependencies. In some embodiments, over an operating temperature range (e.g., −40 to +85 C), the resistance R_{FB} (resistance of reference pixel 1808A) and R_{PIX} (resistance of active pixel 1708B-1708D) can vary over one order of magnitude. For example, if the bolometer conductivity has an activation energy of about 0.19 eV, corresponding to a room-temperature TCR of 2.5%/° K, then the ratio of the resistances at −40 C to that at +85 C is:

$$\frac{R ( - 40 ° C}{R ( + 85 ° C )} \approx 27$$

where R is either R_{FB} or R_{PIX0}. The ratio R_{FB}/R_{PIX0} may not vary with temperature but can be a non-unity constant due to process variations. Since the thermal conductance may not vary over that same range, the gain variation with temperature may follow the product I_{BIAS}*TCR and the offset variation with temperature follows I_{BIAS}. In some embodiments, TCR is also monotonic with temperature and for the 2.5%/° K number changes from 4.1%/° K at −40 C to 1.76%/° K at +85 C, a factor of 2.4.

Operation of the readout circuit illustrated in FIG. 18 may require that the ADC input voltage VADCIN to remain constant and equal to the bias generator feedback voltage VBIAS_FB. In some embodiments, this is achieved as illustrated in FIG. 19 using transistors 1916A and 1916B. Both VADCIN and VBIAS_FB are set by V_{REFB} and the gate-source voltage of the transistors 1916A and 1916B, V_{GS}:

VBIAS_FB=VADCIN=V_{REFB}+V_{GS}

Matching of VBIAS_FB and VADCIN, and stability of VADCIN, may be achieved. A voltage variation at the input of the ADC during conversion is isolated from VADCIN and so may not affect the input current, I_{IN}. In some embodiments, V_{REFB} is the same as V_{REFA}. In some embodiments, V_{REFB} is an independently buffered reference voltage to prevent disturbance on V_{REFA} during the ADC conversion appearing at VADCIN.

In some embodiments, part of the ADC function may be combined with the bias current generation in the readout circuit. FIG. 20 shows an example of one channel of the readout circuit with a sigma-delta (ZA) ADC comprising the sigma-delta modulator (SDM) 2002 and decimation filter 2004. At the start of the SDM is a summing node that combines the input current (I_{IN}−I_{BIAS}) with a feedback current (±AΔ). The combined current is passed to an integrator and subsequent stages of the SDM. The circuit samples the combined input at a high frequency, with the final digital (quantized) output controlling the next feedback sample. The final digital output is obtained by filtering the 1-bit output stream from the SDM with the decimation filter, in some embodiments, to produce a 12- to 16-bit output.

An example of the feedback current generation and current summing functions are combined with the bias current source is illustrated in FIG. 21. The digital output from the SDM 2104 is used to adjust the bias resistor by amounts of +ΔR and −ΔR under the control of the control logic 2020. The +ΔR and −ΔR values may be chosen such that the skim current passing through the resistor is I_{BIAS}±ΔI, where ΔI is the appropriate current increment for the ADC.

$$- Δ R = - {R}_{BIAS} \cdot \frac{Δ I}{{I}_{BIAS} + Δ I}$$

$$+ Δ R = {R}_{BIAS} \cdot \frac{Δ I}{{I}_{BIAS} - Δ I}$$

The net result may be that the input current to the SDM is modified, as if the feedback currents had been added in the summing stage. In some embodiments, the bias current may return to I_{BIAS} between each application of I_{BIAS}±ΔI to improve linearity.

While the gain variation with temperature may be determined by the characteristics of the pixel, the offset may be impacted by the radiation load presented by the camera body housing (associated with the electronic device) that appear within the field of view of the pixel. In some embodiments, a disclosed electronic device comprises a shutter used to cancel offset in a one-point correction process. In some embodiments, the gain and offset are calibrated by a multi-factorial characterization process. For example, the camera temperature is set at a number of temperatures across the operating range and a calibrated blackbody can be presented to the camera and the camera output stored (by a memory coupled to the electronic device). By storing the data and later using a FPA temperature measurement in operation, a set of gain and offset data may be interpolated from the stored values to continuously update the camera associated with the electronic device, a shutterless operation may be realized.

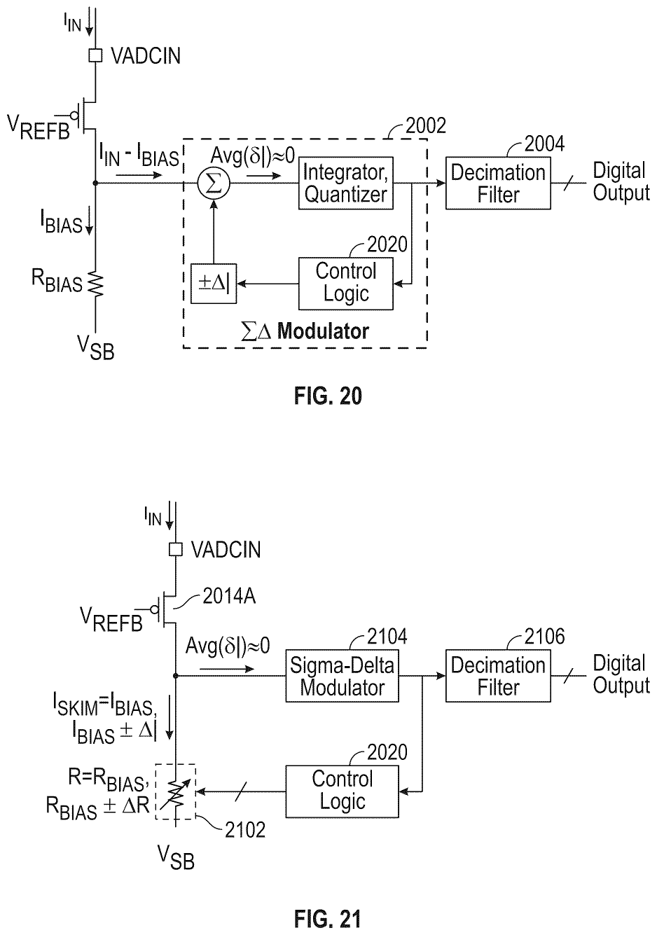

FIG. 22 illustrates a method 2200 of manufacturing an electromechanical system, in accordance with an embodiment. As non-limiting examples, the electrochemical system could be associated with the devices or systems (e.g., electronic device 100, electronic device 200, electronic device described with respect to FIGS. 3-21) described herein. To manufacture an electromechanical system, all or some of the process steps in method 2200 could be used and used in a different order. In some embodiments, steps of 2200 are performed with other electronic device fabrication steps disclosed herein (e.g., described with respect to FIGS. 3-6C, 9A-9C, 13A-14) to fabricate an electronic device.

Method 2200 includes Step 2202, providing a substrate. In some embodiments, the provided substrate comprises substrate 112, substrate 220, or a substrate described with respect to FIGS. 3-17. In some embodiments, the substrate is made of glass. In some embodiments, the substrate is low temperature polycrystalline silicon. In some embodiments, the substrate is a borosilicate that contains additional elements to fine tune properties. An example of a borosilicate is by Corning Eagle™, which produces an alkaline earth boro aluminosilicate (a silicate loaded with boron, aluminum, and various alkaline earth elements). Other variations are available from Asahi Glass™ or Schott™.

In some embodiments, a flat panel glass process is used to manufacture the electromechanical system. In some embodiments, a liquid crystal display (LCD) process is used to manufacture the electromechanical system. In some embodiments, an OLED display process or an x-ray panel process is used. Employing a flat panel glass process may allow for increased substrate sizes, thereby allowing for a higher number of electrochemical systems per substrate, which reduces processing costs. Substrate sizes for “Panel Level” can include 620 mm×750 mm, 680 mm×880 mm, 1100 mm×1300 mm, 1300 mm×1500 mm, 1500 mm×1850 mm, 1950 mm×2250 mm, and 2200 mm×2500 mm. Further, thin film transistors (TFTs) in panel level manufacturing can also reduce cost and so, for example, LCD-TFT processes can be beneficial.

Method 2200 includes Step 2204, adding MEMS to the substrate. Although MEMS is used to describe the addition of structures, it should be appreciated that other structures could be added without deviating from the scope of this disclosure. In embodiments using panel level processing, the MEMS structures may be added using an LCD-TFT process.

Step 2204 may be followed by optional Step 2216, sub-plating. Step 2216 may be used when the substrate is larger than the processing equipment used in subsequent steps. For example, if using a panel level process (such as LCD), some embodiments will include (at Step 2204) cutting the panel into wafer sizes to perform further processing (using, for example, CMOS manufacturing equipment). In other embodiments, the same size substrate is used throughout method 2200 (i.e., Step 2216 is not used).

Method 2200 includes Step 2206, releasing the MEMS from the substrate.

Method 2200 includes Step 2208, post-release processing. Such post-release processing may prepare the MEMS structure for further process steps, such as planarization. In wafer-level processing, planarization can include chemical mechanical planarization. In some embodiments, the further process steps include etch back, where a photoresist is spun onto the topography to generate a more planar surface, which is then etched. Higher control of the etch time can yield a smoother surface profile. In some embodiments, the further process steps include “spin on glass,” where glass-loaded organic binder is spun onto the topography and the result is baked to drive off organic solvents, leaving behind a surface that is smoother.

Method 2200 includes Step 2210, vacuum encapsulation of the MEMS structure, where necessary. Vacuum encapsulation may be beneficial to prolong device life.

Method 2200 includes Step 2212, singulation. Some embodiments may include calibration and chip programming, which may take into account the properties of the sensors. Methods described herein may be advantageous in glass substrate manufacturing processes because uniformity in glass lithography capabilities is limited. As a further advantage, glass has a lower thermal conductivity and so a glass substrate can be a better thermal insulator; by manufacturing thin structures separating a bolometer pixel from a glass substrate, embodiments herein may better serve to thermally isolate the glass bolometer pixel from the packaging environment.

Method 2200 includes Step 2214, attachment of a readout circuit and flex/PCB attachment. As non-limiting examples, the readout circuits could be associated with devices or systems described herein. Processes and devices described herein may have the further advantage that the area required for signal processing can be much smaller than the sensing area which is dictated by the sensing physics. Typically, sensors are integrated on top of CMOS circuitry, and area driven costs lead to a technology node that is not optimal for the signal processing task. Processes described herein can use a more suitable CMOS and drive down the area required for signal processing, freeing the sensor from any area constraints by leveraging the low cost of FPD (flat panel display) manufacturing. In some embodiments, the readout circuit is specifically designed for sensing a specific electromagnetic wavelength (such as X-Rays, THz, LWIR).

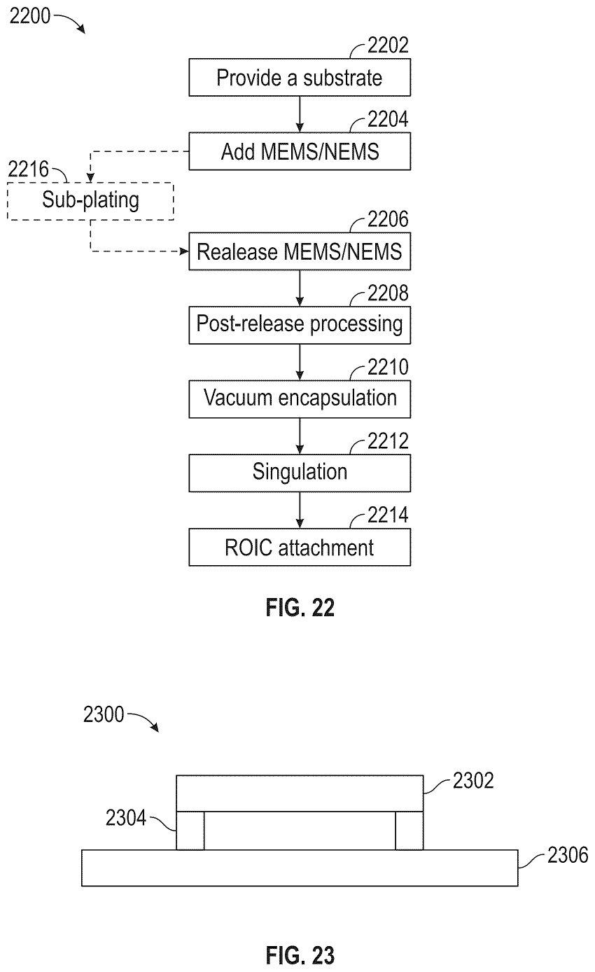

FIG. 23 illustrates an exemplary sensor. In some embodiments, sensor 2300 is manufactured using method 2300. Sensor 2300 includes glass substrate 2306, structure 2304 less than 250 nm wide coupled to glass substrate 2306, and a sensor pixel 2302 coupled to the structure 2304. In some embodiments of sensor 2300, structure 2304 is a hinge that thermally separates the active area from the glass. In some embodiments, sensor 2300 receives an input current or charge and outputs an output current or charge based on the received radiation (e.g., the resistance between two terminals of the sensor changes in response to exposure to LWIR radiation).

In some embodiments, a sensor includes a glass substrate, a structure manufactured from any of the methods described herein and coupled to the glass substrate, and a sensor pixel coupled to the structure.

In some embodiments, a sensor includes a MEMS or NEMS device manufactured by a LCD-TFT manufacturing process and a structure manufactured by any of the methods described herein.

By way of examples, sensors can include resistive sensors and capacitive sensors. Bolometers can be used in a variety of applications. For example, long wave infra-red (LWIR, wavelength of approximately 8-14 μm) bolometers can be used in the automotive and commercial security industries. For example, LWIR bolometers with QVGA, VGA, and other resolution. Terahertz (THz, wavelength of approximately 1.0-0.1 mm) bolometers can be used in security (e.g., airport passenger security screening) and medical (medical imaging). For example, THz bolometers with QVGA resolution and other resolutions. Some electrochemical systems can include X-Ray sensors or camera systems. Similarly, LWIR and THz sensors are used in camera systems. Some electromechanical systems are applied in medical imaging, such as endoscopes and exoscopes. X-ray sensors include direct and indirect sensing configurations.

Other electromechanical systems include scanners for light detection and ranging (LIDAR) systems. For example, optical scanners where spatial properties of a laser beam could be shaped (for, e.g., beam pointing). Electromechanical systems include inertial sensors (e.g., where the input stimulus is linear or angular motion). Some systems may be used in bio sensing and bio therapeutic platforms (e.g., where biochemical agents are detected).

In some embodiments, a method of manufacturing a disclosed electronic device comprises providing components of the electronic device, as described with respect to FIGS. 1-23, and combining, disposing, coupling, and/or creating the components as described with respect to FIGS. 1-23 to manufacture the electronic device.

In some embodiments, a non-transitory computer readable storage medium stores one or more programs, and the one or more programs includes instructions. When the instructions are executed by an electronic device (e.g., a system (e.g., a camera) of electronic device 100 or electronic device 200) with one or more processors and memory, the instructions cause the electronic device to perform the methods described with respect to FIGS. 1-17.

In some embodiments, the electronic device comprises a glass substrate and a plurality of pixels. In some embodiments, the plurality of pixels is configured to absorb radiation. In some embodiments, the plurality of pixels comprises bolometer pixels.

In some embodiments, the electronic device comprises a lid comprising an opening covered by a window cap. In some embodiments, the lid is bonded to the glass substrate.

In some embodiments, the electronic device comprises a sensor array comprising an active area and a dummy pixel area. In some embodiments, the active area comprises the sensors and the dummy pixel area comprises pressure sensors.

In some embodiments, the electronic device is bonded via induction heating.

In some embodiments, the readout values of successive frames from the sensors are averaged in accordance with a determination that a difference between the values are lower than the threshold value.

In some embodiments, the sensors are readout at a first frequency during a first time period and at a second frequency during a second time period.

In some embodiments, residue filaments are attached to the sensors. In some embodiments, the device is thermally isolated from a housing of the device.

In some embodiments, the device comprises a sensor panel, and the sensor panel comprises the sensors and a boundary area. In some embodiments, the boundary area comprises sensors for measuring temperature.

In some embodiments, the device comprises a bias voltage generator for providing a bias voltage to the sensors. In some embodiments, the device comprises a readout circuit for reading out measurements from the sensors.

In some embodiments, an electronic device, comprises a glass substrate; a row of pixels disposed on the glass substrate, wherein the pixels are configured to absorb radiation; a plurality of switches coupled to the row of pixels; and a row circuit coupled to the pluralities of switches. The glass substrate is coupled to a metallized backing, the metallized backing is coupled to a support plate, and the support plate is thermally isolated from a housing of the electronic device.

In some embodiments, the metallized backing comprises a sputtered metal.

In some embodiments, the glass substrate is coupled to the metallized backing via solder.

In some embodiments, the row circuit is configured to switch the plurality of switches at a first frequency during a first time period and at a second frequency during a second time period.

In some embodiments, harmonics of the second frequency do not equal a resonance frequency of the electronic device.

In some embodiments, an average based on first frequency and the second frequency is a readout frequency of the electronic device, and a multiple of the readout frequency equals a resonance frequency of the electronic device.

In some embodiments, the device further comprises residue filaments attached to the row of pixels.

In some embodiments, each pixel of the row of pixels comprises holes.

In some embodiments, the device further comprises second pixels disposed on a boundary of the glass substrate, wherein the second pixels are configured to measure a temperature of the electronic device.

In some embodiments, the device further comprises a bias voltage generator configured to provide a bias voltage to the row of pixels.

In some embodiments, the device further comprises a reference pixel. The bias voltage is generated based on the reference pixel, a size of the reference pixel is greater than a size of one pixel of the row of pixels, and a resistance of the reference pixel and a resistance of the one pixel are equal.

In some embodiments, a method of manufacturing an electronic device comprises: providing a glass substrate; providing a row of pixels, wherein the pixels are configured to absorb radiation; disposing the row of pixels on the glass substrate; providing a plurality of switches; coupling the plurality of switches to the row of pixels; providing a row circuit; coupling the row circuit to the pluralities of switches; providing a metallized backing; coupling the metallized backing to the glass substrate; providing a support plate; coupling the support plate to the metallized backing; providing attachments; coupling the attachments to the support plate; and coupling the attachments to a housing of the electronic device, wherein the attachments are configured for thermally isolating the support plate from the housing of the electronic device.

In some embodiments, the providing the metallized backing comprises sputtering metal.

In some embodiments, the coupling the metallized backing to the glass substrate comprises soldering the metallized backing and the glass substrate.

In some embodiments, the method further comprises disposing residue filaments on the row of pixels.

In some embodiments, the method further comprises creating holes in each pixel of the row of pixels.

In some embodiments, the method further comprises disposing second pixels on a boundary of the glass substrate, wherein the second pixels are configured to measure a temperature of the electronic device.

In some embodiments, a method for operating an electronic device, the electronic device comprises: a row of pixels, wherein the pixels are configured to absorb radiation; a plurality of switches coupled to the row of pixels; and a row circuit coupled to the pluralities of switches, and the method comprises: switching, via the row circuit, the plurality of switches at a first frequency during a first time period; and switching, via the row circuit, the plurality of switches at a second frequency during a second time period.

In some embodiments, multiples of the second frequency do not equal a resonance frequency of the electronic device.

In some embodiments, the method further comprises providing, via a bias voltage generator of the electronic device, a bias voltage to the row of pixels.

Although “electrically coupled” and “coupled” are used to describe the electrical connections between two electronic components or elements in this disclosure, it is understood that the electrical connections do not necessarily need direct connection between the terminals of the components or elements being coupled together. For example, electrical routing connects between the terminals of the components or elements being electrically coupled together. In another example, a closed (conducting or an “on”) switch is connected between the terminals of the components being coupled together. In yet another example, additional elements connect between the terminals of the components being coupled together without affecting the characteristics of the circuit. For example, buffers, amplifiers, and passive circuit elements can be added between components or elements being coupled together without affecting the characteristics of the disclosed circuits and departing from the scope of this disclosure.

Those skilled in the art will recognize that the systems described herein are representative, and deviations from the explicitly disclosed embodiments are within the scope of the disclosure. For example, some embodiments include additional sensors or cameras, such as cameras covering other parts of the electromagnetic spectrum, can be devised using the same principles. As another example, some embodiments include electronic devices comprising sensors other than bolometers.

Although the disclosed embodiments have been fully described with reference to the accompanying drawings, it is to be noted that various changes and modifications will become apparent to those skilled in the art. Such changes and modifications are to be understood as being included within the scope of the disclosed embodiments as defined by the appended claims.

The terminology used in the description of the various described embodiments herein is for the purpose of describing particular embodiments only and is not intended to be limiting. As used in the description of the various described embodiments and the appended claims, the singular forms “a”, “an,” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

1. An electronic device, comprising:
a glass substrate;
a row of pixels disposed on the glass substrate, wherein the pixels are configured to absorb radiation;
a plurality of switches coupled to the row of pixels; and
a row circuit coupled to the pluralities of switches, wherein:
the glass substrate is coupled to a metallized backing,
the metallized backing is coupled to a support plate, and
the support plate is thermally isolated from a housing of the electronic device.

2. The device of claim 1, wherein the metallized backing comprises a sputtered metal.

3. The device of claim 1, wherein the glass substrate is coupled to the metallized backing via solder.

4. The device of claim 1, wherein the row circuit is configured to switch the plurality of switches at a first frequency during a first time period and at a second frequency during a second time period.

5. The device of claim 4, wherein harmonics of the second frequency do not equal a resonance frequency of the electronic device.

6. The device of claim 4, wherein:
an average based on first frequency and the second frequency is a readout frequency of the electronic device, and
a harmonic of the readout frequency equals a resonance frequency of the electronic device.

7. The device of claim 1, further comprising residue filaments attached to the row of pixels.

8. The device of claim 1, wherein each pixel of the row of pixels comprises holes.

9. The device of claim 1, further comprising second pixels disposed on a boundary of the glass substrate, wherein the second pixels are configured to measure a temperature of the electronic device.

10. The device of claim 1, further comprising a bias voltage generator configured to provide a bias voltage to the row of pixels.

11. The device of claim 10, further comprising a reference pixel, wherein:
the bias voltage is generated based on the reference pixel,
a size of the reference pixel is greater than a size of one pixel of the row of pixels, and
a resistance of the reference pixel and a resistance of the one pixel are equal.

12. A method of manufacturing an electronic device, comprising:
providing a glass substrate;
providing a row of pixels, wherein the pixels are configured to absorb radiation;
disposing the row of pixels on the glass substrate;
providing a plurality of switches;
coupling the plurality of switches to the row of pixels;
providing a row circuit;
coupling the row circuit to the pluralities of switches;
providing a metallized backing;
coupling the metallized backing to the glass substrate;
providing a support plate;
coupling the support plate to the metallized backing;
providing attachments;
coupling the attachments to the support plate; and
coupling the attachments to a housing of the electronic device, wherein the attachments are configured for thermally isolating the support plate from the housing of the electronic device.

13. The method of claim 12, wherein the providing the metallized backing comprises sputtering metal.

14. The method of claim 12, wherein the coupling the metallized backing to the glass substrate comprises soldering the metallized backing and the glass substrate.

15. The method of claim 12, further comprising disposing residue filaments on the row of pixels.

16. The method of claim 12, further comprising creating holes in each pixel of the row of pixels.

17. The method of claim 12, further comprising disposing second pixels on a boundary of the glass substrate, wherein the second pixels are configured to measure a temperature of the electronic device.

18. A method for operating an electronic device comprising:
a row of pixels, wherein the pixels are configured to absorb radiation;
a plurality of switches coupled to the row of pixels; and
a row circuit coupled to the pluralities of switches, the method comprising:
switching, via the row circuit, the plurality of switches at a first frequency during a first time period; and
switching, via the row circuit, the plurality of switches at a second frequency during a second time period.

19. The method of claim 18, wherein harmonics of the second frequency do not equal a resonance frequency of the electronic device.

20. The method of claim 18, further comprising providing, via a bias voltage generator of the electronic device, a bias voltage to the row of pixels.
